(19) United States
(12) Patent Application Publication
(10) Pub. No.: US 2025/0055231 A1
(43) Pub. Date: Feb. 13, 2025

(54) MATING MODULE, ELECTRICAL CONNECTOR AND ASSEMBLY THEREOF WITH IMPROVED SHIELDING EFFECT

(71) Applicant: DONGGUAN LUXSHARE TECHNOLOGIES CO., LTD, Dongguan City (CN)

(72) Inventors: Hengshan CHENG, Dongguan City (CN); Hongji CHEN, Dongguan City (CN); Chenhui ZENG, Dongguan City (CN)

(73) Assignee: DONGGUAN LUXSHARE TECHNOLOGIES CO., LTD, Dongguan City (CN)

(21) Appl. No.: 18/631,431

(22) Filed: Apr. 10, 2024

(30) Foreign Application Priority Data
Aug. 10, 2023 (CN) 202311007151.5

(51) Int. Cl. H01R 13/6582; H01R 12/73

(52) U.S. Cl. CPC H01R 13/6582; H01R 12/737

(57) ABSTRACT

A mating module includes a tongue plate configured to be inserted into a mating slot of an electrical connector. The tongue plate includes a first surface, a second surface opposite to the first surface, a number of conductive pads exposed to the first surface and/or the second surface, and at least one metal grounding plate located between the first surface and the second surface. An end surface of the metal grounding plate extends at least close to an edge of the tongue plate. The end surface of the metal grounding plate is configured to be electrically connected to a metal shielding sheet of the electrical connector, so as to improve the grounding and shielding effects. A connector assembly having the mating module is also disclosed.

### CROSS-REFERENCE TO RELATED APPLICATION

This patent application claims priority of a Chinese Patent Application No. 202311007151.5, filed on Aug. 10, 2023 and titled “MATING MODULE, ELECTRICAL CONNECTOR AND ASSEMBLY THEREOF”, the entire content of which is incorporated herein by reference.

### TECHNICAL FIELD

The present disclosure relates to a mating module, an electrical connector and a connector assembly thereof, which belongs to a technical field of connectors.

### BACKGROUND

A connector assembly in the related art generally includes an electrical connector and a mating module mated with the electrical connector. The electrical connector generally includes an insulating body, a terminal module assembled to the insulating body, and a ground shield. The terminal module includes a plurality of conductive terminals. In some electrical connectors, the plurality of conductive terminals include a plurality of differential signal terminal pairs and a plurality of ground terminals located on two sides of each differential signal terminal pair. The ground shield is in contact with all the ground terminals to improve the shielding effect.

The mating module typically includes a tongue plate. A plurality of conductive pads are provided on at least one surface of the tongue plate. The plurality of conductive pads are configured to be in contact with the plurality of conductive terminals of the electrical connector.

However, as the signal transmission quality of the connector assembly is getting higher and higher, the mating module, the electrical connector and the assembly thereof in the related art still need to be further improved.

### SUMMARY

An object of the present disclosure is to provide a mating module, an electrical connector and a connector assembly thereof with improved shielding effect.

In order to achieve the above object, the present disclosure adopts the following technical solution: a mating module, including: a tongue plate configured to be inserted into a mating slot of an electrical connector; the tongue plate including a first surface, a second surface opposite to the first surface, a conductive pad exposed to the first surface and/or the second surface, and at least one layer of metal grounding plate located between the first surface and the second surface; an end surface of the metal grounding plate extending at least adjacent to an edge of the tongue plate; the end surface of the metal grounding plate being configured to be electrically connected to a metal shielding sheet of the electrical connector.

In order to achieve the above object, the present disclosure adopts the following technical solution: an electrical connector, including: an insulating body including a mating surface and a mating slot extending through the mating surface; the mating slot being configured to receive at least part of a mating module along an insertion direction; the mating module being configured to include a first surface, a second surface opposite to the first surface, a conductive pad exposed to the first surface and/or the second surface, and at least one layer of metal grounding plate located between the first surface and the second surface; an end surface of the metal grounding plate extending at least adjacent to an edge of the mating module; a plurality of first conductive terminals, each first conductive terminal including a first contact portion protruding into the mating slot; the first contact portion being configured to be in contact with the conductive pad of the mating module; and a metal shielding sheet including a first abutting portion protruding into the mating slot along a second direction opposite to the insertion direction; the first abutting portion being configured to be electrically connected to the end surface of the metal grounding plate.

In order to achieve the above object, the present disclosure adopts the following technical solution: a connector assembly, including: a mating module, the mating module including a tongue plate; the tongue plate including a first surface, a second surface opposite to the first surface, a conductive pad exposed to the first surface and/or the second surface, and at least one layer of metal grounding plate located between the first surface and the second surface; an end surface of the metal grounding plate extending at least adjacent to an edge of the tongue plate; and an electrical connector including an insulating body, a plurality of first conductive terminals and a metal shielding sheet; the insulating body including a mating surface and a mating slot extending through the mating surface; the mating slot being configured to receive at least part of the mating module along an insertion direction; each first conductive terminal including a first contact portion protruding into the mating slot; the first contact portion being configured to be in contact with the conductive pad of the mating module; the metal shielding sheet including a first abutting portion protruding into the mating slot along a second direction opposite to the insertion direction; the first abutting portion being configured to be electrically connected to the end surface of the metal grounding plate.

Compared with the prior art, the mating module in the present disclosure includes at least one layer of metal grounding plate. The end surface of the metal grounding plate extends at least adjacent to the edge of the tongue plate. The end surface of the metal grounding plate is configured to be electrically connected to the metal shielding sheet of the electrical connector. Such arrangement improves the grounding shielding effect of the mating module, the electrical connector and the connector assembly of the present disclosure, and improves the quality of signal transmission.

### BRIEF DESCRIPTION OF DRAWINGS

FIG. 1 is a schematic perspective view of a connector assembly in accordance with a first embodiment of the present disclosure;

FIG. 2 is a partial perspective exploded view of FIG. 1;

FIG. 3 is a top view of a circuit board in FIG. 2;

FIG. 4 is a partial enlarged view of a frame part B in FIG. 3;

FIG. 5 is a front view after removing the circuit board in FIG. 2;

FIG. 6 is a rear view after removing the circuit board in FIG. 2;

FIG. 7 is a schematic sectional view taken along line C-C in FIG. 5;

FIG. 8 is a partially enlarged view of a frame part D in FIG. 7;

FIG. 9 is a schematic cross-sectional view of the electrical connector in FIG. 7;

FIG. 10 is a partial perspective exploded view of the electrical connector shown in FIG. 2;

FIG. 11 is a partial enlarged view of a frame part E in FIG. 10;

FIG. 12 is a partial perspective exploded view of FIG. 10 from another angle;

FIG. 13 is a top view after removing mounting feet in FIG. 10;

FIG. 14 is a bottom view of FIG. 13;

FIG. 15 is a left view after removing an insulating body in FIG. 13;

FIG. 16 is a perspective exploded view of a plurality of first terminal modules, a first metal shielding sheet, a second metal shielding sheet, a plurality of third metal shielding sheets and a plurality of fourth metal shielding sheets;

FIG. 17 is a further perspective exploded view of FIG. 16;

FIG. 18 is a perspective exploded view of FIG. 17 from another angle;

FIG. 19 is a perspective exploded view of a plurality of second terminal modules, a fifth metal shielding sheet, a sixth metal shielding sheet, a plurality of seventh metal shielding sheets and a plurality of eighth metal shielding sheets;

FIG. 20 is a perspective exploded view of FIG. 19 from another angle;

FIG. 21 is a right side view of the first metal shielding sheet, the second metal shielding sheet, the third metal shielding sheet and the fourth metal shielding sheet;

FIG. 22 is a front view of FIG. 21;

FIG. 23 is a schematic cross-sectional view taken along line F-F in FIG. 1;

FIG. 24 is a schematic cross-sectional view taken along line H-H in FIG. 1;

FIG. 25 is a partially enlarged view of a circled part I in FIG. 24;

FIG. 26 is a schematic perspective view of the connector assembly in accordance with a second embodiment of the present disclosure;

FIG. 27 is a perspective exploded view of FIG. 26;

FIG. 28 is a right view of the mating module in FIG. 27;

FIG. 29 is a partially enlarged view of a circled part J in FIG. 28;

FIG. 30 is a right side view of the electrical connector in FIG. 27 after partial components are disassembled;

FIG. 31 is a right view of a plurality of metal shielding sheets in FIG. 30 when they are mated with the mating module;

FIG. 32 is a partially enlarged view of a frame part K in FIG. 31;

FIG. 33 is a partial perspective exploded view of the electrical connector in FIG. 27;

FIG. 34 is a partially enlarged view of a frame part L in FIG. 33;

FIG. 35 is a schematic perspective view of the mating module in accordance with a third embodiment of the present disclosure;

FIG. 36 is a partial enlarged view of a circled part N in FIG. 35;

FIG. 37 is a schematic perspective view of the connector assembly in accordance with a fourth embodiment of the present disclosure;

FIG. 38 is a partial perspective exploded view of FIG. 37;

FIG. 39 is a further perspective exploded view of FIG. 38;

FIG. 40 is a perspective exploded view of FIG. 39 from another angle;

FIG. 41 is a left side view of FIG. 39;

FIG. 42 is a schematic view when the mating module in the fourth embodiment is inserted into the electrical connector in the fourth embodiment, wherein the insulating body of the electrical connector is not shown;

FIG. 43 is a partially enlarged view of a circled part O in FIG. 41;

FIG. 44 is a partially enlarged view of a circled part P in FIG. 42;

FIG. 45 is a schematic perspective view of the mating module installed on a circuit board in accordance with a fifth embodiment of the present disclosure;

FIG. 46 is a partial perspective exploded view of the mating module shown in FIG. 45;

FIG. 47 is a partially enlarged view of a circled part Q in FIG. 46; and

FIG. 48 is a partially enlarged view of FIG. 47 in another embodiment.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

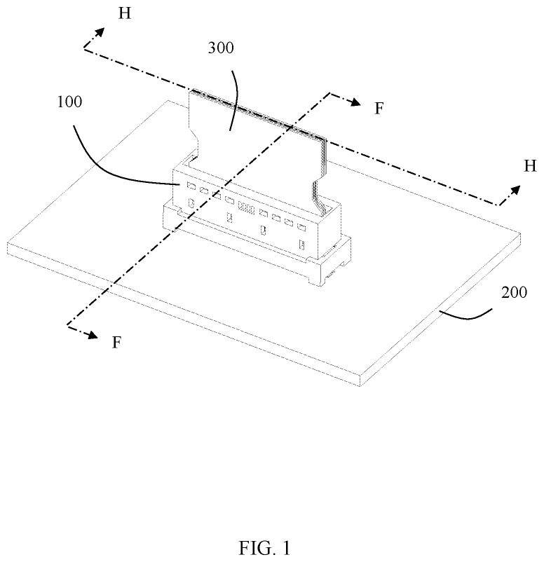

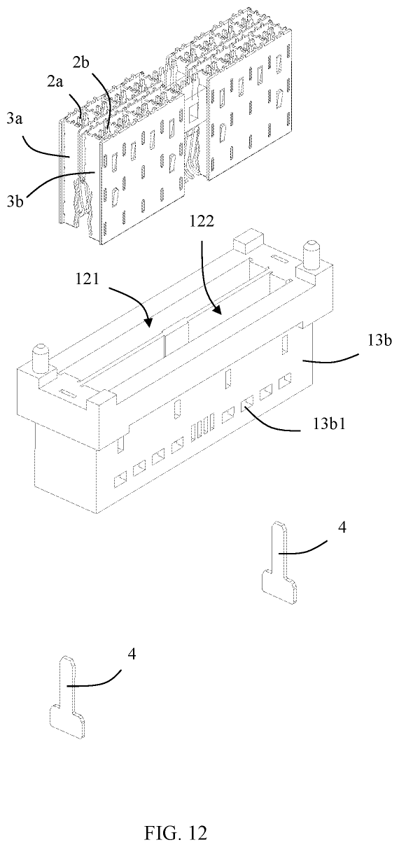

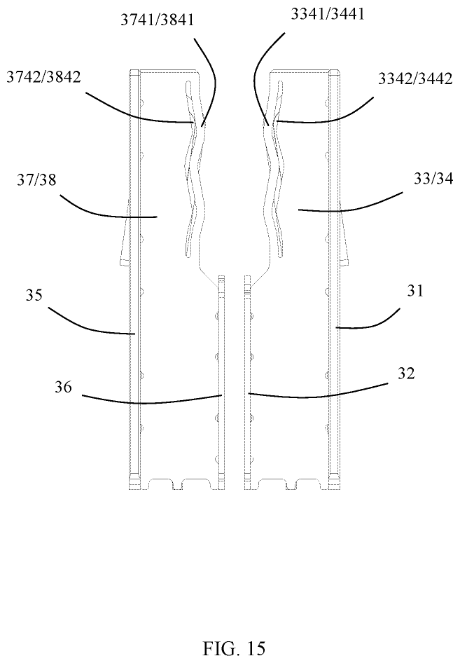

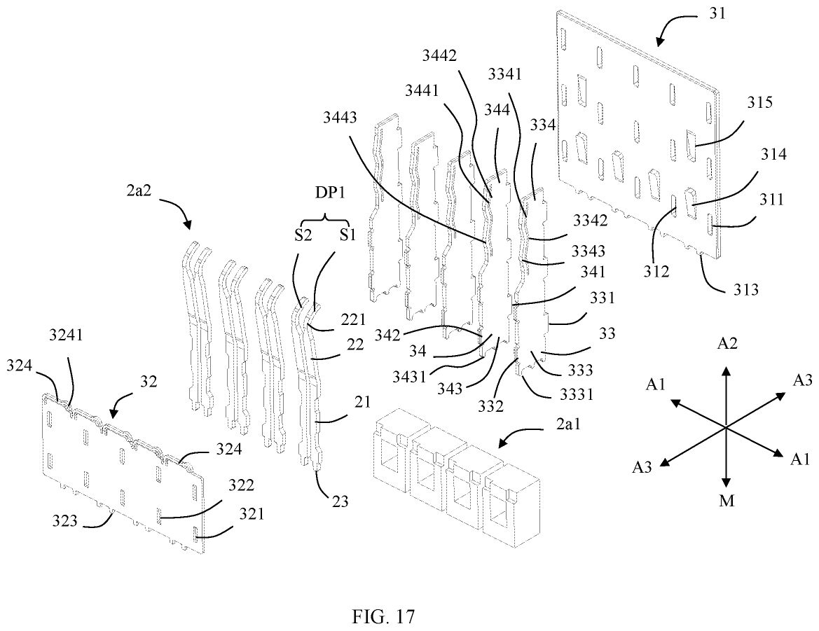

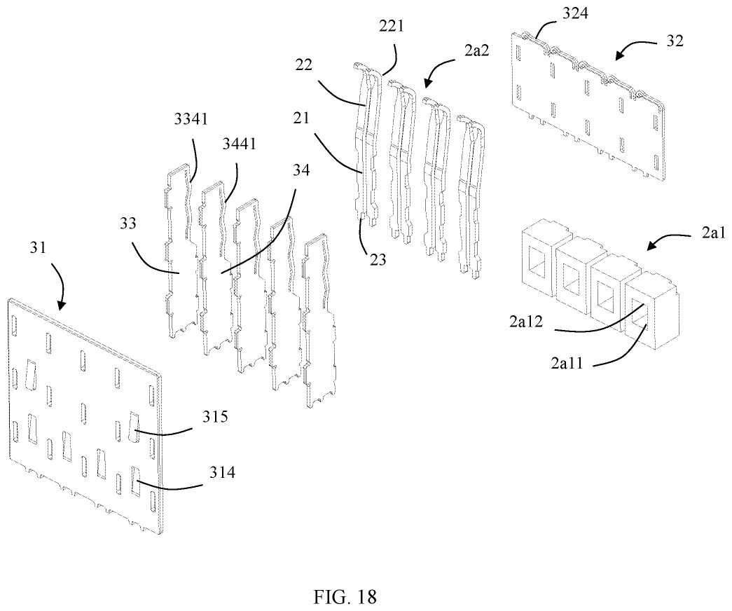

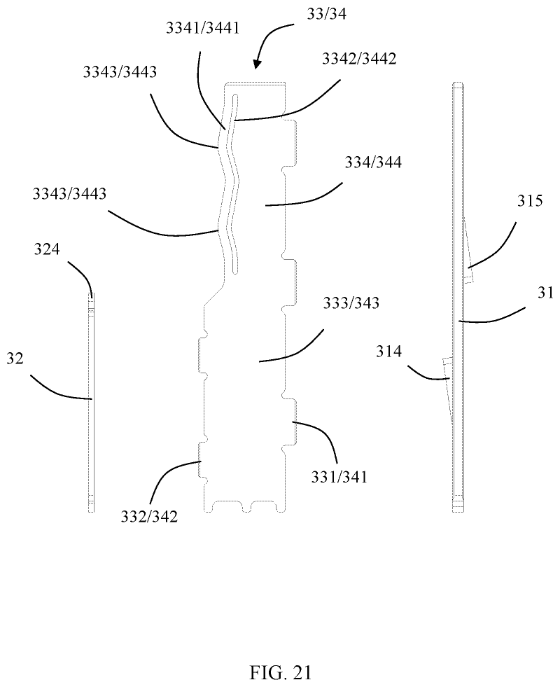

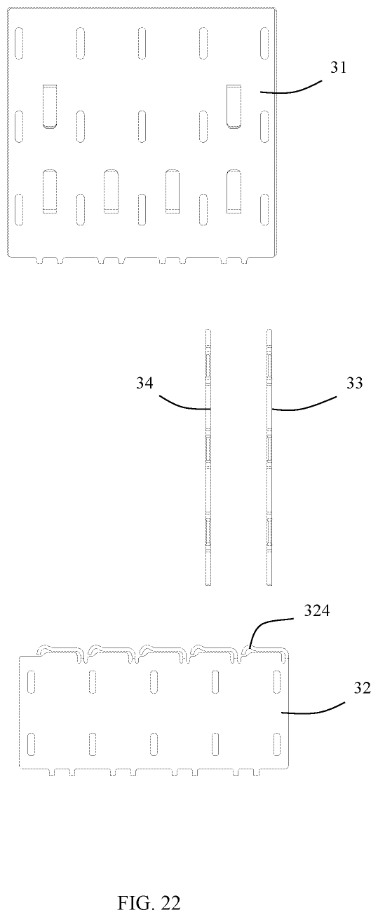

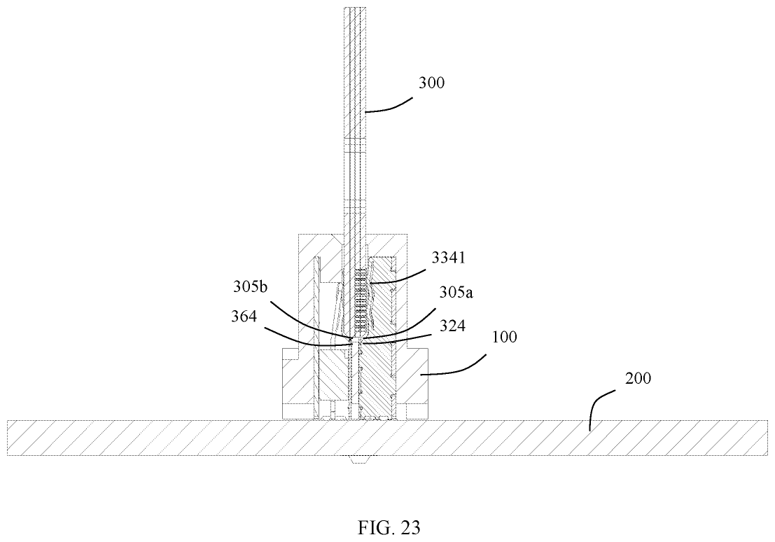

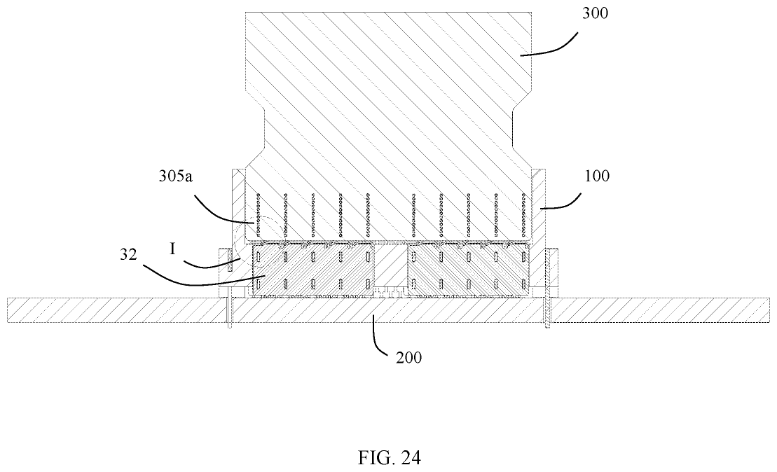

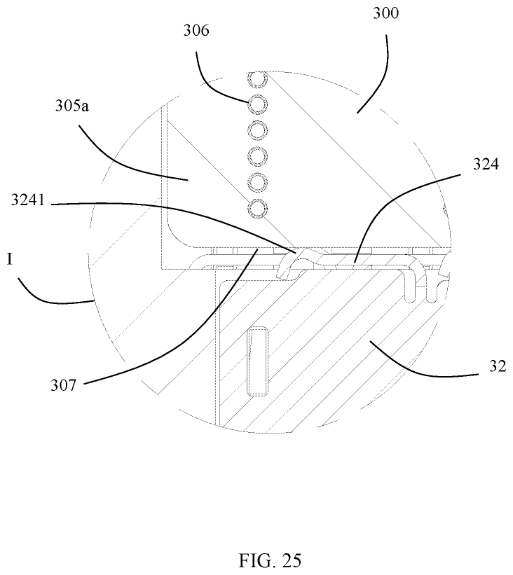

Referring to FIG. 1 to FIG. 25, the first illustrated embodiment of the present disclosure discloses an electrical connector 100, which includes an insulating body 1, a plurality of first terminal modules 2a assembled to the insulating body 1, a plurality of second terminal modules 2b assembled to the insulating body 1, a first shielding assembly 3a surrounding the first terminal modules 2a, a second shielding assembly 3b surrounding the second terminal modules 2b, and a pair of mounting feet 4 fixed to the insulating body 1.

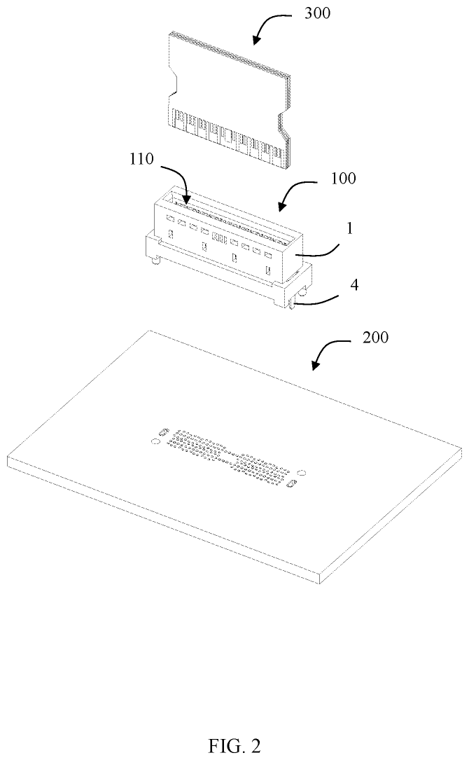

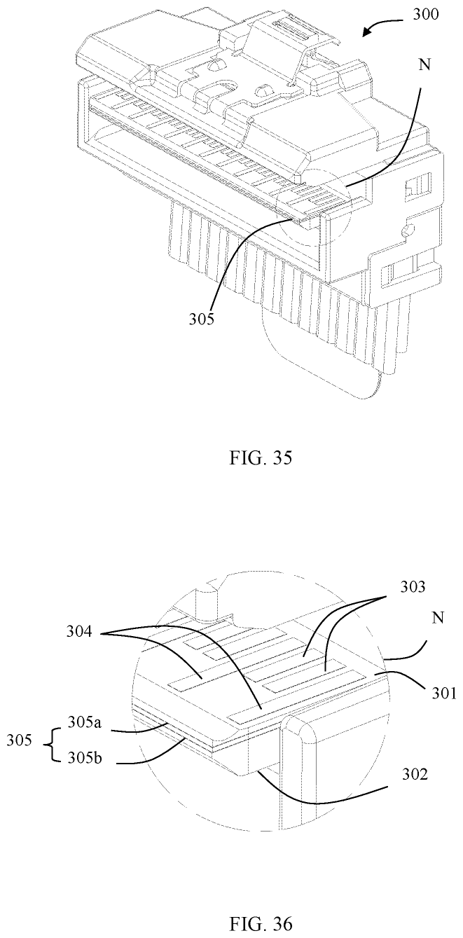

Referring to FIG. 1 and FIG. 2, in the embodiment shown in the present disclosure, the electrical connector 100 is configured to be mounted to a circuit board 200 and configured to be plugged with a mating module 300. The mounting feet 4 are used to fix the electrical connector 100 to the circuit board 200. In one embodiment of the present disclosure, the mating module 300 is an electronic card, and the electrical connector 100 is a card edge connector accordingly. The electronic card includes a tongue plate. In one embodiment, the tongue plate is a mating circuit board which is configured for being inserted into the electrical connector 100. Of course, it is understandable to those skilled in the art that the mating module 300 can also be a mating connector (for example, shown in FIG. 35). The mating connector has a mating circuit board (in this case a built-in circuit board). The mating circuit board is configured for being inserted into the electrical connector 100.

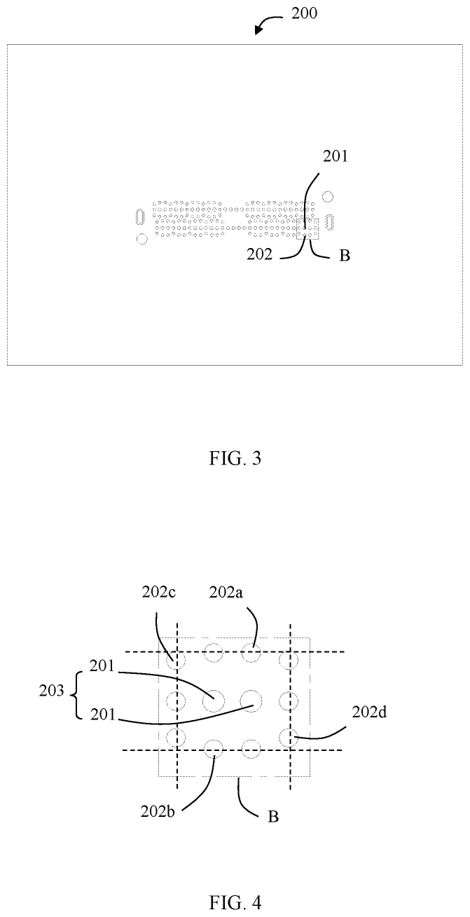

Referring to FIG. 3 and FIG. 4, the circuit board 200 includes a plurality of signal contacts 201 and a plurality of ground contacts 202. In the illustrated embodiment of the present disclosure, the plurality of signal contacts 201 are arranged in a manner of differential signal contacts 203. Each differential signal contacts 203 include two adjacent signal contacts 201. In order to improve the shielding effect, each differential signal contacts 203 is surrounded by a plurality of ground contacts 202. Specifically, the plurality of ground contacts 202 include a plurality of first ground contacts 202a located on a first side of the differential signal contacts 203, a plurality of second ground contacts 202b located on a second side of the differential signal contacts 203, a plurality of third ground contacts 202c located on a third side of the differential signal contacts 203, and a plurality of fourth ground contacts 202d located on a fourth side of the differential signal contacts 203. In the illustrated embodiment of the present disclosure, the signal contacts 201 and the ground contacts 202 are circular conductive pads disposed on an upper surface of the circuit board 200. An area of each of the signal contacts 201 is greater than an area of any one of the ground contacts 202.

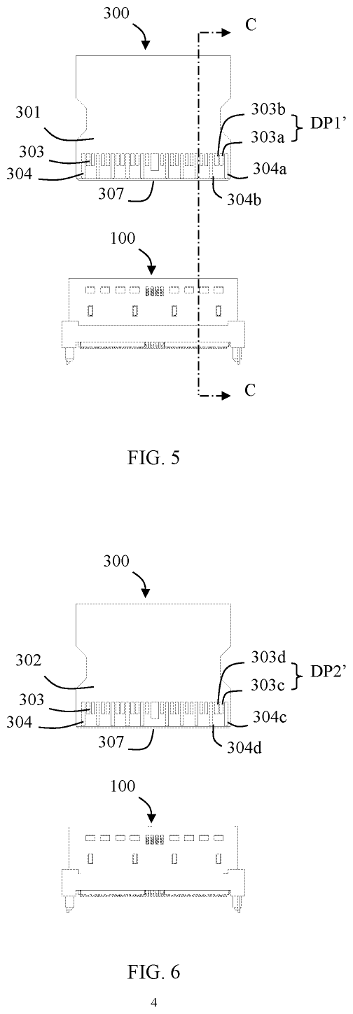

Referring to FIG. 5 to FIG. 8, the mating circuit board of the mating module 300 includes a first surface 301, a second surface 302 opposite to the first surface 301, a plurality of signal pads 303 exposed to the first surface 301 and the second surface 302, a plurality of ground pads 304 exposed to the first surface 301 and the second surface 302, and a plurality of layers of metal grounding plates 305 located between the first surface 301 and the second surface 302.

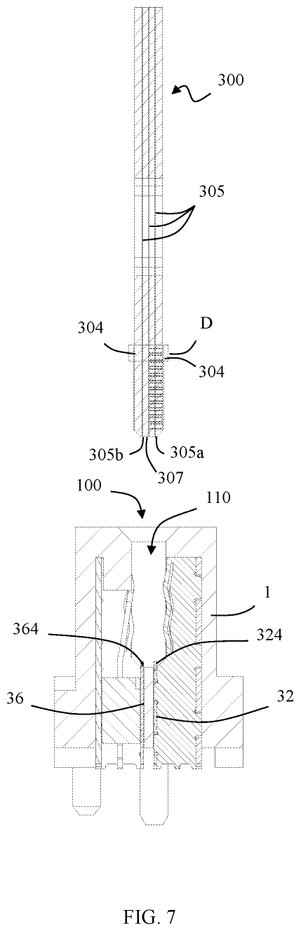

Referring to FIG. 5 and FIG. 6, in the embodiment shown in the present disclosure, the plurality of signal pads 303 include a plurality of first signal pads 303a exposed to the first surface 301, a plurality of second signal pads 303b exposed to the first surface 301, a plurality of third signal pads 303c exposed to the second surface 302, and a plurality of fourth signal pads 303d exposed to the second surface 302. The first signal pad 303a and the second signal pad 303b which is located adjacent to the first signal pad 303a together form a first differential pair signal pad DP1′. The third signal pad 303c and the fourth signal pad 303d which is located adjacent to the third signal pad 303c together form a second differential pair signal pad DP2′.

In the illustrated embodiment of the present disclosure, the plurality of ground pads 304 include a plurality of first ground pads 304a exposed to the first surface 301, a plurality of second ground pads 304b exposed to the first surface 301, a plurality of third ground pads 304c exposed to the second surface 302, and a plurality of fourth ground pads 304d exposed to the second surface 302. Two sides of each first differential pair signal pad DP1′ is associated with one first ground pad 304a and one second ground plane 304b, respectively, so as to improve the quality of signal transmission. Two sides of each second differential pair signal pad DP2′ are associated with one third ground pad 304c and one fourth ground pad 304d, respectively, so as to improve the quality of signal transmission.

In the embodiment shown in the present disclosure, a length of any one of the first ground pads 304a and any one of the second ground pads 304b is greater than a length of any one of the first signal pads 303a and any one of the second signal pads 303b, so as to improve the shielding effect.

Similarly, in the illustrated embodiment of the present disclosure, a length of any one of the third ground pads 304c and any one of the fourth ground pads 304d is greater than a length of any one of the third signal pads 303c and any one of the fourth signal pads 303d, so as to improve the shielding effect.

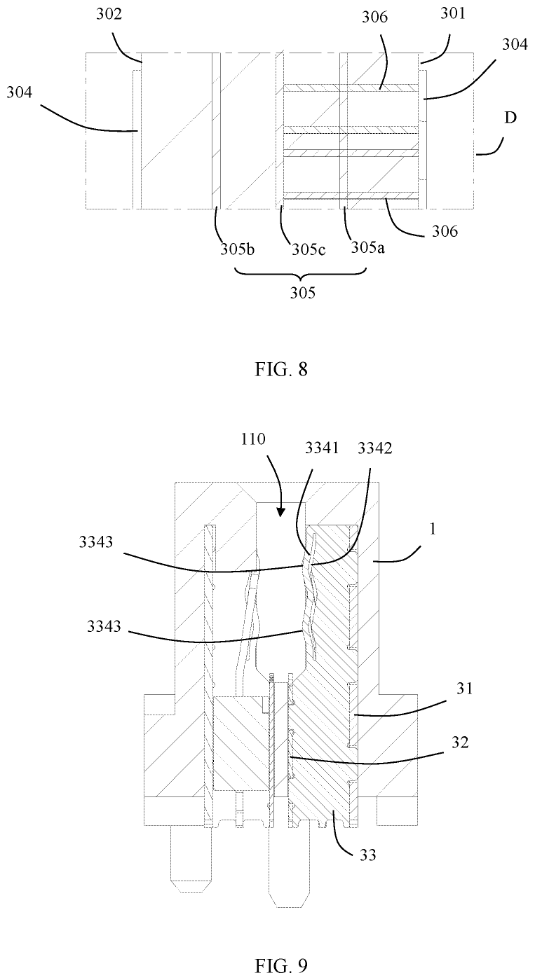

Referring to FIG. 7 and FIG. 8, the plurality of layers of metal grounding plates 305 include a first metal grounding plate 305a, a second metal grounding plate 305b and a third metal grounding plate 305c which are arranged at intervals along a thickness direction of the mating circuit board. The third metal grounding plate 305c is located between the first metal grounding plate 305a and the second metal grounding plate 305b. The mating circuit board further includes a plurality of conductive holes 306 extending along the thickness direction of the mating circuit board (FIG. 8 only schematically shows part of the conductive holes 306). Some of the plurality of conductive holes 306 connect the plurality of first ground pads 304a and the plurality of second ground pads 304b with the first metal grounding plate 305a and the third metal grounding plate 305c in series. Another some of the plurality of conductive holes 306 connect the plurality of third ground pads 304c and the plurality of fourth ground pads 304d with the second metal grounding plate 305b and the third metal grounding plate 305c in series. As a result, the plurality of first ground pads 304a, the plurality of second ground pads 304b, the plurality of third ground pads 304c, the plurality of fourth ground pads 304d, the first metal grounding plate 305a, the second metal grounding plate 305b and the third metal grounding plate 305c are all connected in series to form a whole, so as to increase the shared grounding area and improve the quality of signal transmission.

In the illustrated embodiment of the present disclosure, the mating circuit board includes an end surface 307 at a lower end thereof. The first metal grounding plate 305a, the second metal grounding plate 305b and the third metal grounding plate 305c are all exposed downwardly to the end surface 307. In other words, the first metal grounding plate 305a, the second metal grounding plate 305b and the third metal grounding plate 305c can be observed from a bottom surface of the mating circuit board. Of course, it is understandable to those skilled in the art that, in some embodiments, the first metal grounding plate 305a, the second metal grounding plate 305b and the third metal grounding plate 305c may protrude downwardly beyond the end surface 307 so as to improve the reliability of contacting a metal shielding sheet of the electrical connector 100.

In the present disclosure, by providing the plurality of layers of metal grounding plates 305, the signal pads 303 on two sides of the plurality of layers of metal grounding plates 305 can be internally isolated, thereby reducing crosstalk. In addition, by exposing the first metal grounding plate 305a, the second metal grounding plate 305b and the third metal grounding plate 305c downwardly to the end surface 307, they can be in contact with a shielding assembly of the electrical connector 100 so as to improve the shielding effect (details will be described later).

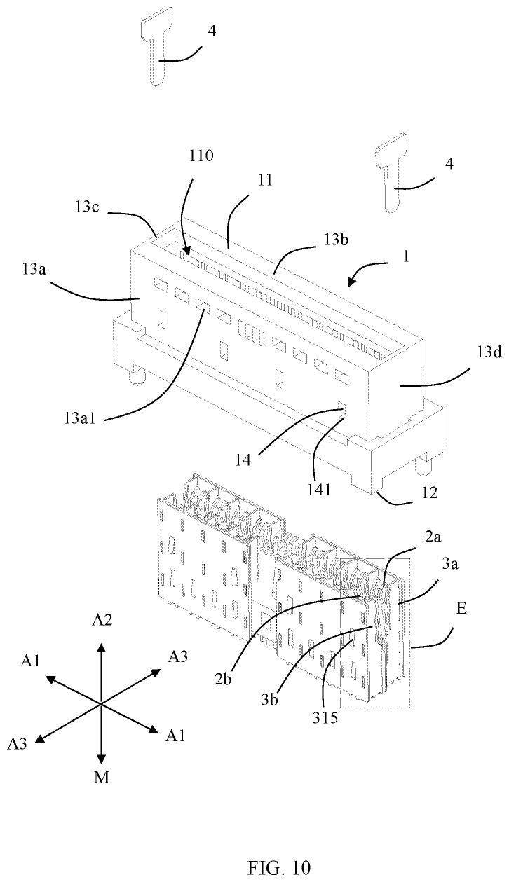

Referring to FIG. 10 to FIG. 12, the insulating body 1 includes a mating surface 11, a mating slot 110 extending through the mating surface 11, a mounting surface 12 opposite to the mating surface 11, a first installation slot 121 extending through the mounting surface 12, and a second installation slot 122 extending through the mounting surface 12. Both the first installation slot 121 and the second installation slot 122 communicate with the mating slot 110. The mating slot 110 is configured to receive at least part of the mating circuit board along an insertion direction M (for example, a top-to-bottom direction). The first installation slot 121 and the second installation slot 122 are used for installing shielding assemblies and for receiving terminal modules.

Referring to FIG. 10, the insulating body 1 includes a first side wall 13a, a second side wall 13b opposite to the first side wall 13a, a third side wall 13c connecting one end of the first side wall 13a and one end of the second side wall 13b, and a fourth side wall 13d connecting the other end of the first side wall 13a and the other end of the second side wall 13b. The mating slot 110 is jointly enclosed by the first side wall 13a, the second side wall 13b, the third side wall 13c and the fourth side wall 13d.

In order to improve heat dissipation, the first side wall 13a further defines a plurality of first heat dissipation holes 13al extending through the first side wall 13a and communicating with the mating slot 110. Similarly, the second side wall 13b further defines a plurality of second heat dissipation holes 13b1 extending through the second side wall 13b and communicating with the mating slot 110.

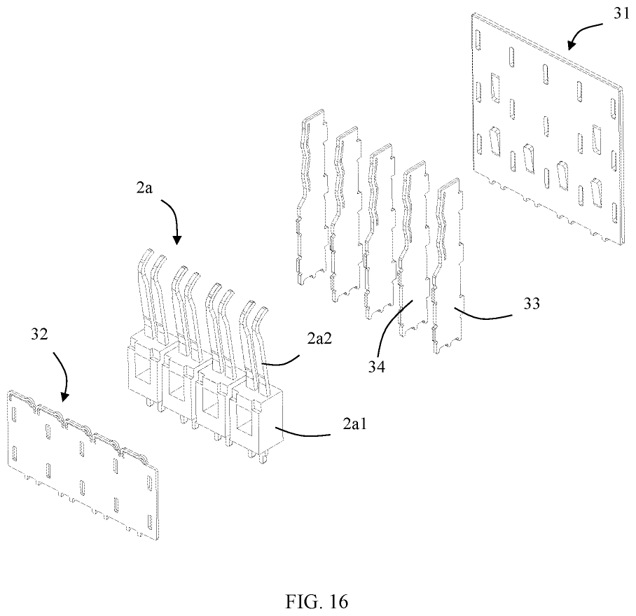

Referring to FIG. 16 to FIG. 18, in the embodiment shown in the present disclosure, each first terminal module 2a includes a first insulating block 2al and a plurality of first conductive terminals 2a2 fixed to the first insulating block 2al. In an embodiment of the present disclosure, the plurality of first conductive terminals 2a2 are insert-molded with the first insulating block 2a1. Each first conductive terminal 2a2 includes a first fixing portion 21 fixed to the first insulating block 2a1, a first elastic arm 22 extending upwardly from one end of the first fixing portion 21, and a first tail portion 23 extending downwardly from the other end of the first fixing portion 21. The first elastic arm 22 includes a first contact portion 221 protruding into the mating slot 110. The first tail portion 23 extends along a vertical direction.

The plurality of first conductive terminals 2a2 includes at least one signal terminal. In the illustrated embodiment of the present disclosure, the at least one signal terminal includes a first signal terminal S1 and a second signal terminal S2 which is located adjacent to the first signal terminal S1. The first signal terminal S1 and the second signal terminal S2 are arranged side by side along a first direction A1-A1 (for example, a left-right direction). The first signal terminal S1 and the second signal terminal S2 which is located adjacent to the first signal terminal S1 along the first direction A1-A1 together form a terminal group. In the illustrated embodiment of the present disclosure, the terminal group is a first differential signal terminal pair DP1. The first direction A1-A1 is perpendicular to the insertion direction M.

The first shielding assembly 3a includes a first metal shielding sheet 31, a second metal shielding sheet 32, a plurality of third metal shielding sheets 33 and a plurality of fourth metal shielding sheets 34. In the illustrated embodiment of the present disclosure, the first metal shielding sheet 31, the second metal shielding sheet 32, the third metal shielding sheets 33 and the fourth metal shielding sheets 34 are separated components, but assembled together. It is understandable to those skilled in the art that the first metal shielding sheet 31, the second metal shielding sheet 32, the third metal shielding sheets 33 and the fourth metal shielding sheets 34 may also be in one-piece structure, or at least two metal shielding sheets in one-piece structure.

In the illustrated embodiment of the present disclosure, the first metal shielding sheet 31 is located on a first side of the first differential signal terminal pair DP1. The second metal shielding sheet 32 is disposed opposite to the first metal shielding sheet 31; the second metal shielding sheet 32 is located on a second side of the first differential signal terminal pair DP1. The third metal shielding sheet 33 is disposed between the first metal shielding sheet 31 and the second metal shielding sheet 32; the third metal shielding sheet 33 is located on a third side of the first differential signal terminal pair DP1. The fourth metal shielding sheet 34 is disposed between the first metal shielding sheet 31 and the second metal shielding sheet 32; the fourth metal shielding sheet 34 is disposed opposite to the third metal shielding sheet 33; the fourth metal shielding sheet 34 is located on a fourth side of the first differential signal terminal pair DP1. The first side of the first differential signal terminal pair DP1, the second side of the first differential signal terminal pair DP1, the third side of the first differential signal terminal pair DP1, and the fourth side of the first differential signal terminal pair DP1 are the front, rear, left and right of the first differential signal terminal pair DP1. The first metal shielding sheet 31, the second metal shielding sheet 32, the third metal shielding sheet 33 and the fourth metal shielding sheet 34 are disposed around a periphery of the first differential signal terminal pair DP1 to improve the shielding effect.

In the illustrated embodiment of the present disclosure, the first metal shielding sheet 31, the second metal shielding sheet 32, the third metal shielding sheets 33 and the fourth metal shielding sheets 34 are all stamped from metal sheets. The first metal shielding sheet 31, the second metal shielding sheet 32, the third metal shielding sheets 33 and the fourth metal shielding sheets 34 are assembled by splicing. Optionally, after splicing, the connection among the first metal shielding sheet 31, the second metal shielding sheet 32, the third metal shielding sheets 33 and the fourth metal shielding sheets 34 can be strengthened by means of soldering, welding or the like, if needed.

In the illustrated embodiment of the disclosure, the first metal shielding sheet 31 defines a plurality of first slots 311 and a plurality of second slots 312. The third metal shielding sheet 33 includes a plurality of first protrusions 331 held in the plurality of first slots 311. The fourth metal shielding sheet 34 includes a plurality of second protrusions 341 held in the plurality of second slots 312.

The second metal shielding sheet 32 defines a plurality of third slots 321 and a plurality of fourth slots 322. The third metal shielding sheet 33 includes a plurality of third protrusions 332 held in the plurality of third slots 321. The fourth metal shielding sheet 34 includes a plurality of fourth protrusions 342 held in the plurality of fourth slots 322.

Besides, the first metal shielding sheet 31 further includes a plurality of first mounting protrusions 313 protruding downwardly. The plurality of first mounting protrusions 313 are configured to be in contact with the plurality of first ground pads 304a. The first metal shielding sheet 31 and/or the second metal shielding sheet 32 includes a first locking protrusion 314 protruding inwardly and a second locking protrusion 315 protruding outwardly. The first insulating block 2al includes a first locking groove 2a11 and a first locking surface 2a12 exposed to the first locking groove 2a11. The first locking surface 2a12 abuts against the first locking protrusion 314 along a second direction A2 opposite to the insertion direction M, so as to prevent the first insulating block 2al from detaching. Referring to FIG. 10, the insulating body 1 includes a second locking groove 14 and a second locking surface 141 exposed to the second locking groove 14. The second locking surface 141 abuts against the second locking protrusion 315 along the second direction A2, so as to prevent the first metal shielding sheet 31 and/or the second metal shielding sheet 32 from falling off from the insulating body 1.

The second metal shielding sheet 32 further includes a plurality of second mounting protrusions 323 protruding downwardly. The plurality of second mounting protrusions 323 are configured to be in contact with the plurality of second ground pads 304b. In the illustrated embodiment of the present disclosure, the second metal shielding sheet 32 further includes a plurality of first abutting elastic arms 324 protruding into the mating slot 110 along the second direction. The plurality of first abutting elastic arms 324 are disposed at intervals along the first direction A1-A1. In the illustrated embodiment of the present disclosure, the first abutting elastic arms 324 are integrally formed with the second metal shielding sheet 32. Each first abutting elastic arm 324 is in a cantilever shape. Each first abutting elastic arm 324 has a first abutting portion 3241 protruding into the mating slot 110 along the second direction. The first abutting portion 3241 is configured to be in contact with the first metal grounding plate 305a. As a result, on the one hand, the first abutting elastic arm 324 can provide a certain elastic support for the mating module 300; on the other hand, the first shielding assembly 3a can be connected in series with a whole formed by the plurality of first ground pads 304a, the plurality of second ground pads 304b, the plurality of third ground pads 304c, the plurality of fourth ground pads 304d, the first metal grounding plate 305a, the second metal grounding plate 305b and the third metal grounding plate 305c. Of course, it is understandable to those skilled in the art that the first abutting elastic arm 324 can also be replaced by a structure such as a simply supported beam.

Each third metal shielding sheet 33 includes a first base portion 333 and a first extension portion 334 extending from the first base portion 333 along the second direction A2. A width of the first base portion 333 along the third direction A3-A3 is greater than a width of the first extension portion 334 along the third direction A3-A3. Each two of the first direction A1-A1, the second direction A2 and the third direction A3-A3 are perpendicular with each other. The plurality of first protrusions 331 and the plurality of third protrusions 332 are at least provided on the first base portion 333. The first base portion 333 further includes a plurality of third mounting protrusions 3331 protruding downwardly. The plurality of third mounting protrusions 3331 are configured to be in contact with the plurality of third ground pads 304c.

The first extension portion 334 includes a first elastic simply supported beam 3341 and a first slot 3342 provided for deformation of the first elastic simply supported beam 3341. Two ends of the first elastic simply supported beam 3341 are fixed to the third metal shielding sheet 33, respectively. The first elastic simply supported beam 3341 includes a first elastic engaging portion 3343 protruding into the mating slot 110 along the third direction A3-A3. In the illustrated embodiment of the present disclosure, the first elastic simply supported beam 3341 is wavy or arc-shaped. The first slot 3342 is in a shape matching the shape of the first elastic simply supported beam 3341. Each first elastic simply supported beam 3341 includes two first elastic engaging portions 3343 spaced apart along the second direction A2. The first elastic engaging portions 3343 are configured to abut against the first ground pad 304a.

Similarly, the fourth metal shielding sheet 34 includes a second base portion 343 and a second extension portion 344 extending from the second base portion 343 along the second direction A2. A width of the second base portion 343 along the third direction A3-A3 is greater than a width of the second extension portion 344 along the third direction A3-A3. The plurality of second protrusions 341 and the plurality of fourth protrusions 342 are at least provided on the second base portion 343. The second base portion 343 further includes a plurality of fourth mounting protrusions 3431 protruding downwardly. The plurality of fourth mounting protrusions 3431 are configured to be in contact with the plurality of fourth ground pads 304d.

The second extension portion 344 includes a second elastic simply supported beam 3441 and a second slot 3442 provided for deformation of the second elastic simply supported beam 3441. Two ends of the second elastic simply supported beam 3441 are fixed to the fourth metal shielding sheet 34, respectively. The second elastic simply supported beam 3441 includes a second elastic engaging portion 3443 protruding into the mating slot 110 along the third direction A3-A3. In the illustrated embodiment of the present disclosure, the second elastic simply supported beam 3441 is wavy or arc-shaped. The second slot 3442 is in a shape matching the shape of the second elastic simply supported beam 3441. Each second elastic simply supported beam 3441 includes two second elastic engaging portions 3443 spaced apart along the second direction A2. The second elastic engaging portions 3443 are configured to abut against the second ground pad 304b.

Preferably, in the embodiment illustrated in the present disclosure, the third metal shielding sheet 33 is completely identical to the fourth metal shielding sheet 34, so as to share parts and save costs.

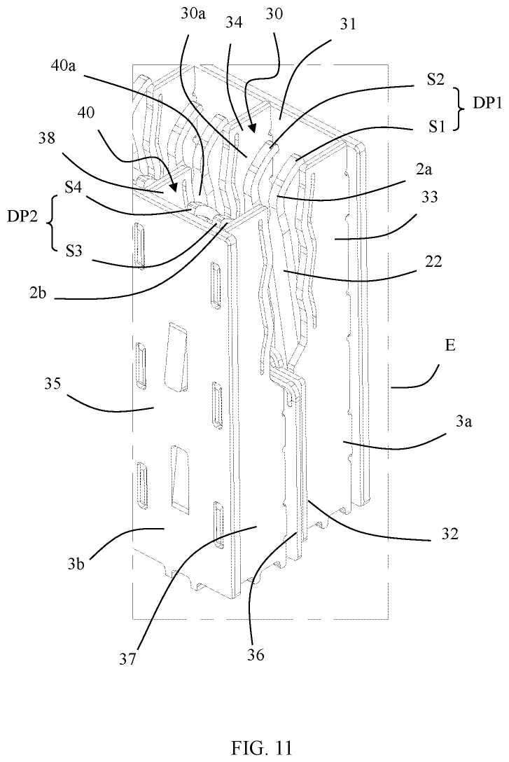

Referring to FIG. 10 and FIG. 11, in the embodiment shown in the present disclosure, the first metal shielding sheet 31, the second metal shielding sheet 32, the third metal shielding sheet 33 and the fourth metal shielding sheet 34 surround a periphery of the first fixing portions 21 of the first differential signal terminal pair DP1.

The first metal shielding sheet 31, the third metal shielding sheet 33, and the fourth metal shielding sheet 34 extend along the second direction A2 to be flush with a top surface of the first conductive terminal 2a2 or beyond the top surface. The second metal shielding sheet 32 is lower than the top surface along the second direction A2.

In other words, the first metal shielding sheet 31, the third metal shielding sheet 33 and the fourth metal shielding sheet 34 form a first U-shaped cavity 30 corresponding to the first elastic arms 22 of the first differential signal terminal pair DP1. The first elastic arms 22 of the first differential signal terminal pair DP1 are located in the first U-shaped cavity 30. The first U-shaped cavity 30 includes a first opening 30a through which the first contact portions 221 protrude into the mating slot 110 along the third direction A3-A3.

In the embodiment shown in the present disclosure, the first metal shielding sheet 31, the third metal shielding sheet 33 and the fourth metal shielding sheet 34 themselves can provide three-sided shielding for the first elastic arms 22 of the first differential signal terminal pair DP1. When the mating module 300 is inserted into the mating slot 110, the first opening 30a is shielded by the first metal grounding plate 305a, so as to finally realize surrounding the first elastic arms 22 of the first differential signal terminal pair DP1. It is understandable to those skilled in the art that the design disclosed in the present disclosure is beneficial to improve the shielding effect of the first differential signal terminal pair DP1, reduce crosstalk, and improve the quality of signal transmission. Therefore, it is suitable for application scenarios with higher requirements on transmission rate and transmission quality.

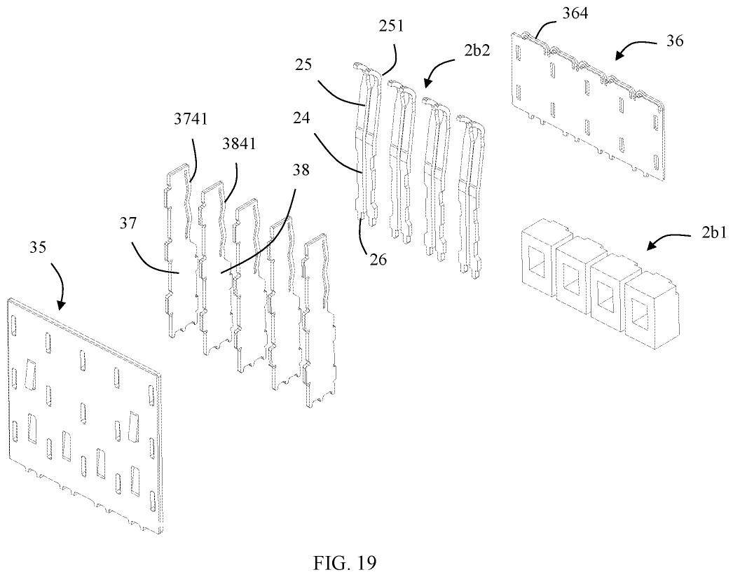

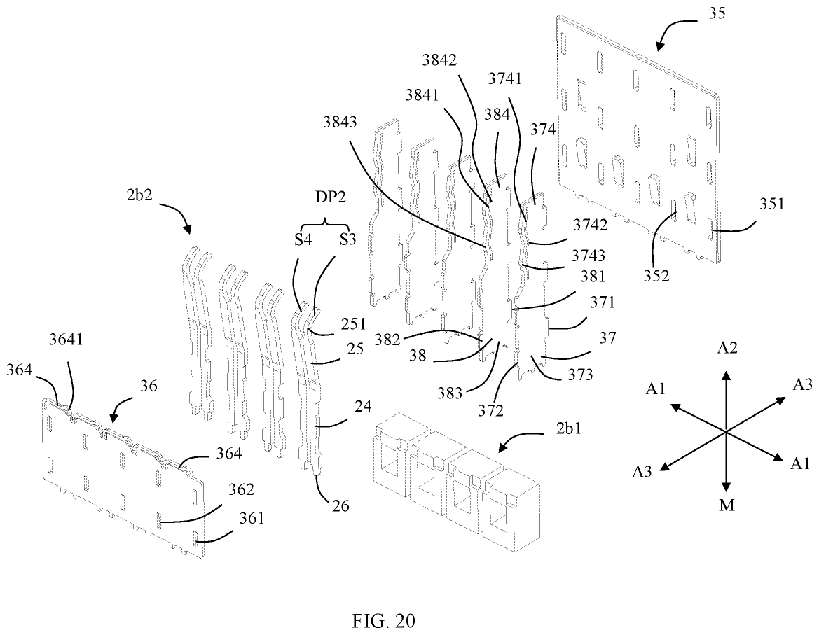

Referring to FIG. 19 and FIG. 20, each second terminal module 2b includes a second insulating block 2b1 and a plurality of second conductive terminals 2b2 fixed to the second insulating block 2b1. In one embodiment of the present disclosure, the plurality of second conductive terminals 2b2 are insert-molded with the second insulating block 2b1. Each second conductive terminal 2b2 includes a second fixing portion 24 fixed to the second insulating block 2b1, a second elastic arm 25 extending upwardly from one end of the second fixing portion 24, and a second tail portion 26 extending downwardly from the other end of the second fixing portion 24. The second elastic arm 25 includes a second contact portion 251 protruding into the mating slot 110. The second tail portion 26 extends along the vertical direction.

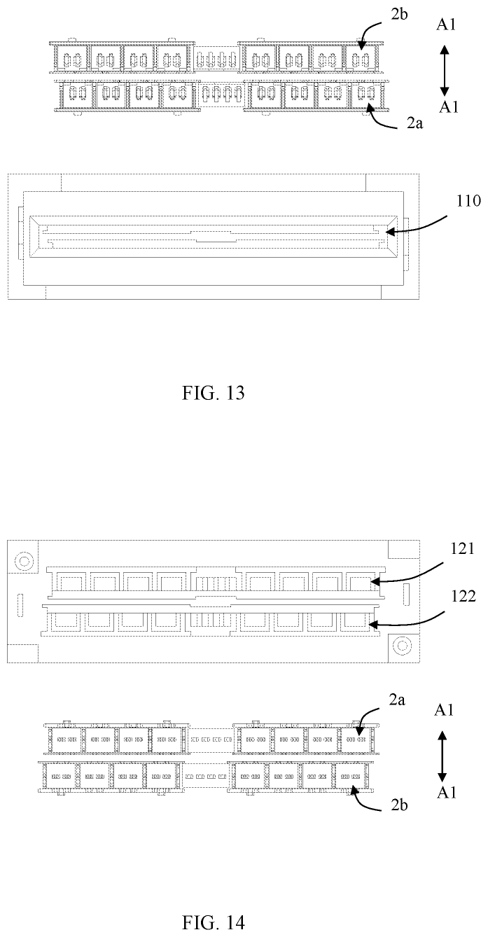

The plurality of second conductive terminals 2b2 include a third signal terminal S3 and a fourth signal terminal S4 which is located adjacent to the third signal terminal S3. The third signal terminal S3 and the fourth signal terminal S4 are disposed side by side along the first direction A1-A1. The third signal terminal S3 and the fourth signal terminal S4 which is located adjacent to the third signal terminal S3 along the first direction A1-A1 together form another terminal group. In the illustrated embodiment of the present disclosure, the another terminal group is a second differential signal terminal pair DP2. Referring to FIG. 13 and FIG. 14, the second differential signal terminal pair DP2 and the first differential signal terminal pair DP1 are staggered along the third direction A3-A3 to further reduce signal crosstalk.

The second shielding assembly 3b includes a fifth metal shielding sheet 35, a sixth metal shielding sheet 36, a plurality of seventh metal shielding sheets 37 and a plurality of eighth metal shielding sheets 38. In the embodiment shown in the present disclosure, the fifth metal shielding sheet 35, the sixth metal shielding sheet 36, the seventh metal shielding sheets 37 and the eighth metal shielding sheets 38 are separated components, but assembled together. It is understandable to those skilled in the art that the fifth metal shielding sheet 35, the sixth metal shielding sheet 36, the seventh metal shielding sheets 37 and the eighth metal shielding sheets 38 may also be in one-piece structure, or at least two metal shielding sheets in one-piece structure.

In the illustrated embodiment of the present disclosure, the fifth metal shielding sheet 35 is located on a first side of the second differential signal terminal pair DP2. The sixth metal shielding sheet 36 is disposed opposite to the fifth metal shielding sheet 35; the sixth metal shielding sheet 36 is located on a second side of the second differential signal terminal pair DP2. The seventh metal shielding sheet 37 is disposed between the fifth metal shielding sheet 35 and the sixth metal shielding sheet 36; the seventh metal shielding sheet 37 is located on a third side of the second differential signal terminal pair DP2. The eighth metal shielding sheet 38 is disposed between the fifth metal shielding sheet 35 and the sixth metal shielding sheet 36; the eighth metal shielding sheet 38 is disposed opposite to the seventh metal shielding sheet 37; the eighth metal shielding sheet 38 is located on a fourth side of the second differential signal terminal pair DP2. The first side of the second differential signal terminal pair DP2, the second side of the second differential signal terminal pair DP2, the third side of the second differential signal terminal pair DP2, and the fourth side of the second differential signal terminal pair DP2 are the front, rear, left and right of the second differential signal terminal pair DP2. The fifth metal shielding sheet 35, the sixth metal shielding sheet 36, the seventh metal shielding sheet 37 and the eighth metal shielding sheet 38 are disposed around the periphery of the second differential signal terminal pair DP2 to improve the shielding effect.

In the illustrated embodiment of the present disclosure, the fifth metal shielding sheet 35, the sixth metal shielding sheet 36, the seventh metal shielding sheets 37, and the eighth metal shielding sheets 38 are all stamped from metal sheets. The fifth metal shielding sheet 35, the sixth metal shielding sheet 36, the seventh metal shielding sheets 37 and the eighth metal shielding sheets 38 are spliced, but assembled together. Optionally, after splicing, the connection among the fifth metal shielding sheet 35, the sixth metal shielding sheet 36, the seventh metal shielding sheet 37 and the eighth metal shielding sheet 38 can be strengthened by means of soldering, welding or the like, if needed.

In the illustrated embodiment of the present disclosure, the fifth metal shielding sheet 35 includes a plurality of fifth slots 351 and a plurality of sixth slots 352. The seventh metal shielding sheet 37 includes a plurality of fifth protrusions 371 held in the plurality of fifth slots 351. The eighth metal shielding sheet 38 includes a plurality of sixth protrusions 381 held in the plurality of sixth slots 352.

The sixth metal shielding sheet 36 includes a plurality of seventh slots 361 and a plurality of eighth slots 362. The seventh metal shielding sheet 37 includes a plurality of seventh protrusions 372 held in the plurality of seventh slots 361. The eighth metal shielding sheet 38 includes a plurality of eighth protrusions 382 held in the plurality of eighth slots 362.

In the illustrated embodiment of the present disclosure, the sixth metal shielding sheet 36 further includes a plurality of second abutting elastic arms 364 protruding into the mating slot 110 along the second direction A2. The plurality of second abutting elastic arms 364 are disposed at intervals along the first direction A1-A1. In the illustrated embodiment of the present disclosure, the second abutting elastic arms 364 are integrally formed with the sixth metal shielding sheet 36. Each second abutting elastic arm 364 is in a cantilever shape. The second abutting elastic arm 364 includes a second abutting portion 3641 protruding into the mating slot 110 along the second direction A2. The second abutting portion 3641 is configured to be in contact with the second metal grounding plate 305b. As a result, on the one hand, the second abutting elastic arm 364 can provide a certain elastic support for the mating module 300; on the other hand, the second shielding assembly 3b can be connected in series with a whole formed by the plurality of first ground pads 304a, the plurality of second ground pads 304b, the plurality of third ground pads 304c, the plurality of fourth ground pads 304d, the first metal grounding plate 305a, the second metal grounding plate 305b and the third metal grounding plate 305c. Of course, it is understandable to those skilled in the art that the second abutting elastic arm 364 can also be replaced by a less elastic structure such as simply supported beam, or even replaced by a non-elastic structure.

The seventh metal shielding sheet 37 includes a third base portion 373 and a third extension portion 374 extending from the third base portion 373 along the second direction A2. A width of the third base portion 373 along the third direction A3-A3 is greater than a width of the third extension portion 374 along the third direction A3-A3. The plurality of fifth protrusions 371 and the plurality of seventh protrusions 372 are at least provided on the third base portion 373.

The third extension portion 374 includes a third elastic simply supported beam 3741 and a third slot 3742 provided for deformation of the third elastic simply supported beam 3741. Two ends of the third elastic simply supported beam 3741 are fixed to the seventh metal shielding sheet 37, respectively. The third elastic simply supported beam 3741 includes a third elastic engaging portion 3743 protruding into the mating slot 110 along the third direction A3-A3. In the illustrated embodiment of the present disclosure, the third elastic simply supported beam 3741 is wavy or arc-shaped. The third slot 3742 is in a shape matching the shape of the third elastic simply supported beam 3741. Each third elastic simply supported beam 3741 includes two third elastic engaging portions 3743 disposed at intervals along the second direction A2. The third elastic engaging portion 3743 is configured to abut against the third ground pad 304c.

Similarly, the eighth metal shielding sheet 38 includes a fourth base portion 383 and a fourth extension portion 384 extending from the fourth base portion 383 along the second direction A2. A width of the fourth base portion 383 along the third direction A3-A3 is greater than a width of the fourth extension portion 384 along the third direction A3-A3. The plurality of sixth protrusions 381 and the plurality of eighth protrusions 382 are at least provided on the fourth base portion 383.

The fourth extending portion 384 includes a fourth elastic simply supported beam 3841 and a fourth slot 3842 provided for deformation of the fourth elastic simply supported beam 3841. Two ends of the fourth elastic simply supported beam 3841 are fixed to the eighth metal shielding sheet 38, respectively. The fourth elastic simply supported beam 3841 includes a fourth elastic engaging portion 3843 protruding into the mating slot 110 along the third direction A3-A3. In the illustrated embodiment of the present disclosure, the fourth elastic simply supported beam 3841 is wavy or arc-shaped. The fourth slot 3842 is in a shape matching the shape of the fourth elastic simply supported beam 3841. Each fourth elastic simply supported beam 3841 is provided with two fourth elastic engaging portions 3843 disposed at intervals along the second direction A2. The fourth elastic engaging portion 3843 is configured to abut against the fourth ground pad 304d.

Preferably, in the illustrated embodiment of the present disclosure, the seventh metal shielding sheet 37 is completely identical to the eighth metal shielding sheet 38, so as to share parts and save costs.

Referring to FIG. 10 and FIG. 11, in the embodiment illustrated in the present disclosure, the fifth metal shielding sheet 35, the sixth metal shielding sheet 36, the seventh metal shielding sheet 37 and the eighth metal shielding sheet 38 surround a periphery of the second fixing portions 24 of the second differential signal terminal pair DP2.

The fifth metal shielding sheet 35, the seventh metal shielding sheet 37 and the eighth metal shielding sheet 38 extend along the second direction A2 to be flush with a top surface of the second conductive terminal 2b2 or beyond the top surface. The sixth metal shielding sheet 36 is lower than the top surface along the second direction A2.

In other words, the fifth metal shielding sheet 35, the seventh metal shielding sheet 37 and the eighth metal shielding sheet 38 form a second U-shaped cavity 40 corresponding to the second elastic arms 25 of the second differential signal terminal pair DP2. The second elastic arms 25 of the second differential signal terminal pair DP2 are located in the second U-shaped cavity 40. The second U-shaped cavity 40 includes a second opening 40a through which the second contact portions 251 protrude into the mating slot 110 along the third direction A3-A3.

In the embodiment shown in the present disclosure, the fifth metal shielding sheet 35, the seventh metal shielding sheet 37 and the eighth metal shielding sheet 38 themselves can provide three-sided shielding for the second elastic arms 25 of the second differential signal terminal pair DP2. When the mating module 300 is inserted into the mating slot 110, the second opening 40a is shielded by the second metal grounding plate 305b, so as to finally realize surrounding the second elastic arms 25 of the second differential signal terminal pair DP2. It is understandable to those skilled in the art that the design disclosed in the present disclosure is beneficial to improve the shielding of the second differential signal terminal pair DP2, reduce crosstalk, and improve the quality of signal transmission. Therefore, it is suitable for application scenarios with higher requirements on transmission rate and transmission quality.

Compared with the prior art, the first metal shielding sheet 31, the second metal shielding sheet 32, the third metal shielding sheet 33 and the fourth metal shielding sheet 34 of the present disclosure are disposed around the periphery of the first differential signal terminal pair DP1 in a surrounding manner. The second metal shielding sheet 32 includes the first abutting portion 3241 protruding into the mating slot 110 along the second direction A2 opposite to the insertion direction M. The first abutting portion 3241 is configured to be electrically connected to (for example, abutting against) the end surface of the first metal grounding plate 305a of the mating module 300. The fifth metal shielding sheet 35, the sixth metal shielding sheet 36, the seventh metal shielding sheet 37 and the eighth metal shielding sheet 38 of the present disclosure are disposed around the periphery of second differential signal terminal DP2. The sixth metal shielding sheet 36 includes the second abutting portion 3641 protruding into the mating slot 110 along the second direction A2 opposite to the insertion direction M. The second abutting portion 3641 is configured to be electrically connected to (for example, abutting against) the end surface of the second metal grounding plate 305b of the mating module 300. Such arrangement improves the shielding effect of the electrical connector 100 and the connector assembly thereof, and improves the quality of signal transmission.

Besides, when the mating module 300 is inserted into the mating slot 110, the first opening 30a is shielded by the first metal grounding plate 305a, and the second opening 40a is shielded by the second metal grounding plate 305b, so as to finally realize surrounding the first elastic arms 22 of the first differential signal terminal pair DP1 and the second elastic arms 25 of the second differential signal terminal pair DP2. This design disclosed in the present disclosure is beneficial to improve the shielding of the first differential signal terminal pair DP1 and the second differential signal terminal pair DP2, reduce crosstalk, and improve the quality of signal transmission. Therefore, it is suitable for application scenarios with higher requirements for transmission rate and transmission quality.

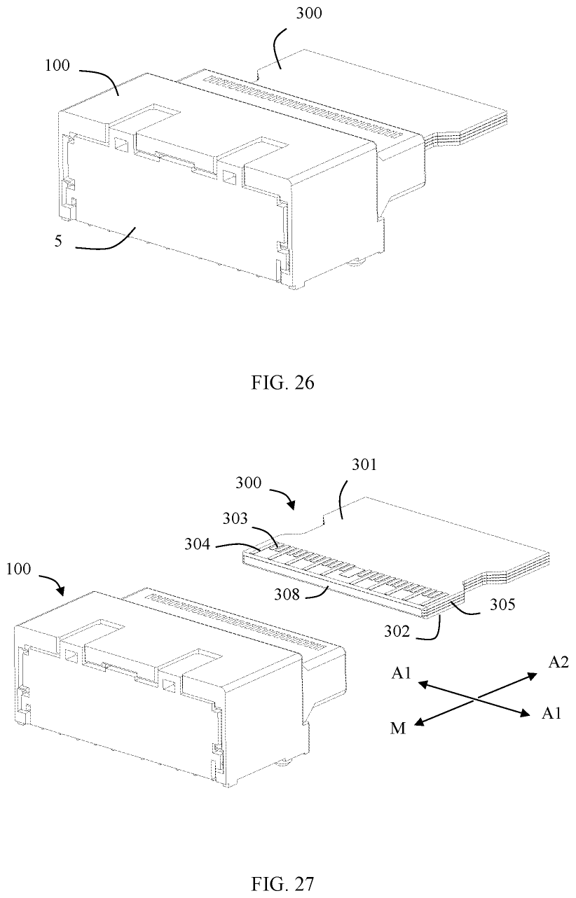

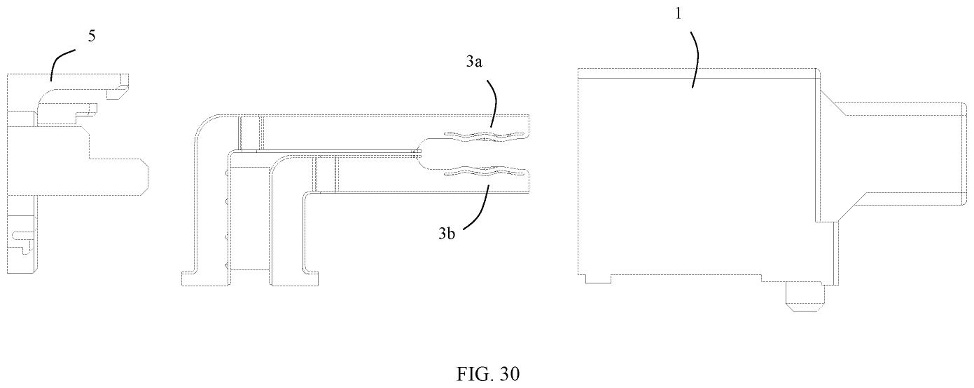

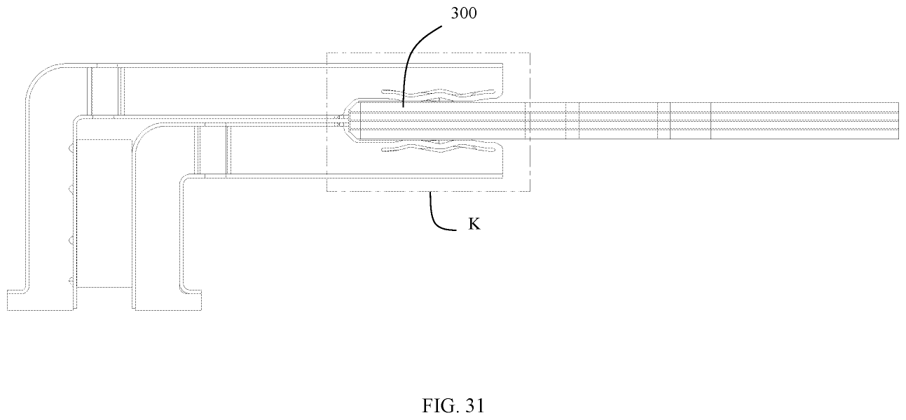

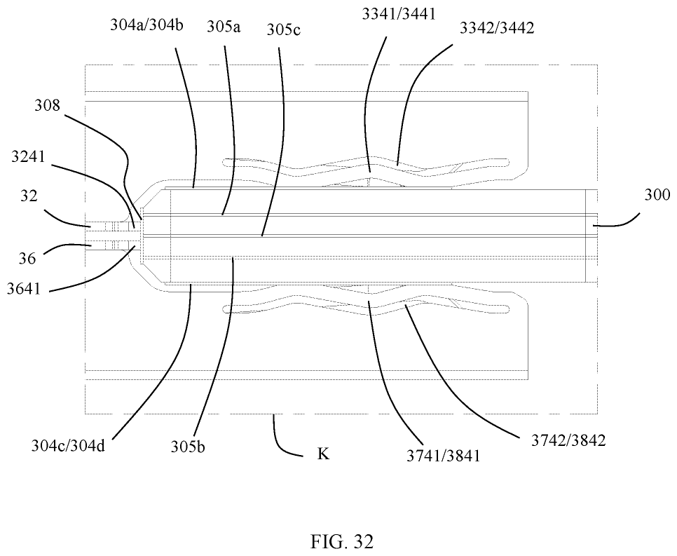

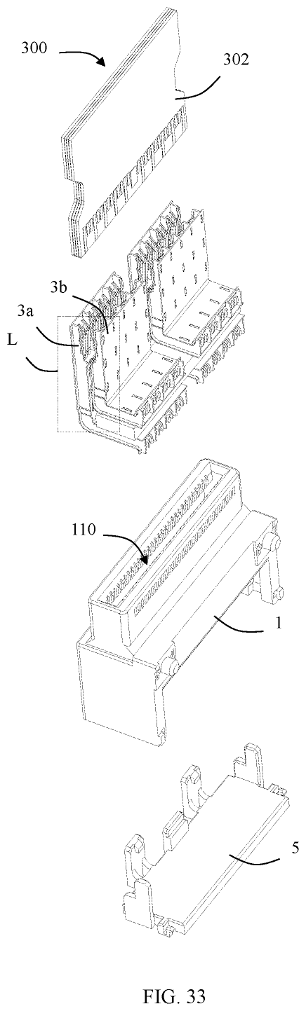

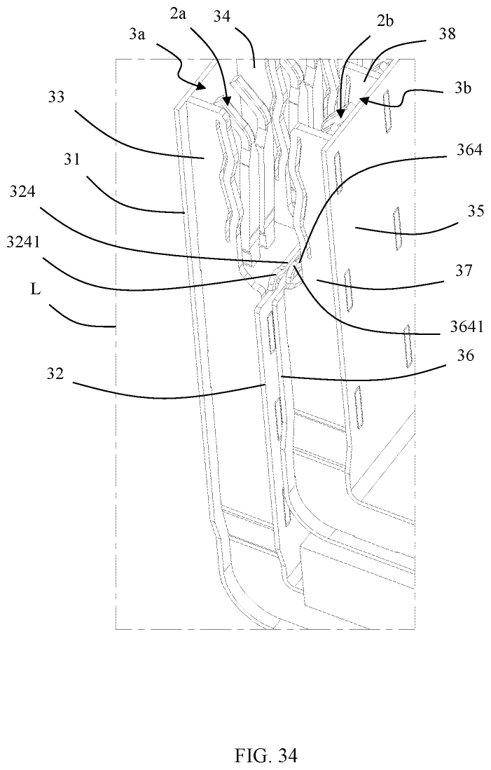

Referring to FIG. 26 to FIG. 34, a second embodiment illustrated in the present disclosure discloses an electrical connector 100, which includes an insulating body 1, a plurality of first terminal modules 2a assembled to the insulating body 1, a plurality of second terminal modules 2b assembled to the insulating body 1, a first shielding assembly 3a surrounding the first terminal modules 2a, a second shielding assembly 3b surrounding the second terminal modules 2b, and a mounting block 5 assembled to the insulating body 1. The electrical connector 100 is configured to be mounted on a circuit board, and configured to be plugged with a mating module 300. In one embodiment of the present disclosure, the mating module 300 is an electronic card, and the electrical connector 100 is a card edge connector accordingly. The electronic card includes a mating circuit board configured for being at least partially inserted into the electrical connector 100. Of course, it is understandable to those skilled in the art that the mating module 300 can also be a mating connector. The mating connector has a mating circuit board (in this case a built-in circuit board). The mating circuit board is configured for being at least partially inserted into the electrical connector 100.

The electrical connector 100 and the mating module 300 disclosed in the second embodiment shown in the present disclosure are similar to the electrical connector 100 and the mating module 300, respectively, disclosed in the first embodiment shown in the present disclosure. For the same or similar parts, please refer to the description of the electrical connector 100 and the mating module 300 in the first embodiment of the present disclosure, which will not be repeated in the present disclosure. Only the differences between the first embodiment and the second embodiment will be described below.

The electrical connector 100 disclosed in the second embodiment shown in the present disclosure is a right-angle connector. The electrical connector 100 is vertically mounted on a circuit board (not shown). The mating slot 110 of the electrical connector 100 extends substantially along a horizontal direction. The mating module 300 is at least partially inserted into the mating slot 110 along the horizontal direction.

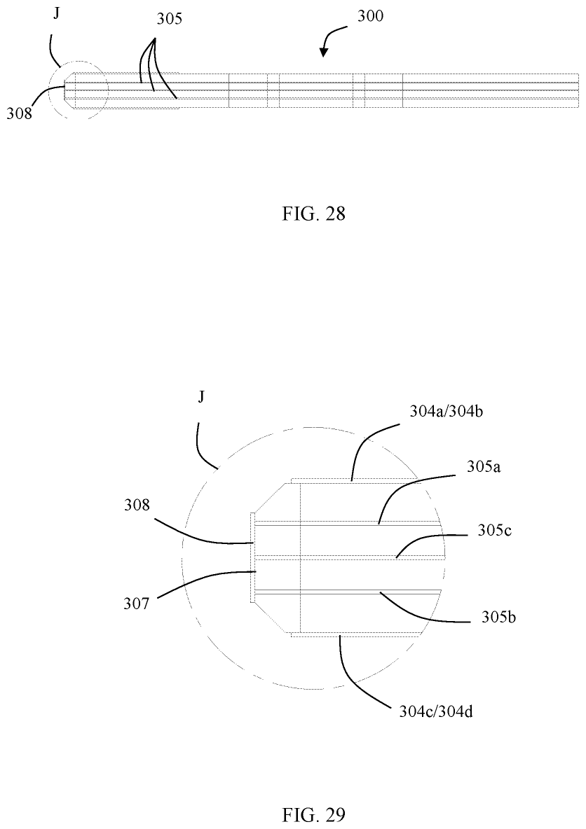

Referring to FIG. 27 and FIG. 28, the mating module 300 includes a tongue plate. In this embodiment, the tongue plate is a mating circuit board. The mating circuit board includes a first surface 301, a second surface 302 opposite to the first surface 301, a plurality of signal pads 303 exposed to the first surface 301 and the second surface 302, a plurality of ground pads 304 exposed to the first surface 301 and the second surface 302, and a plurality of layers of metal grounding plates 305 located between the first surface 301 and the second surface 302.

The plurality of layers of metal grounding plates 305 include a first metal grounding plate 305a, a second metal grounding plate 305b and a third metal grounding plate 305c which are arranged at intervals along a thickness direction of the mating circuit board. The third metal grounding plate 305c is located between the first metal grounding plate 305a and the second metal grounding plate 305b. The mating circuit board further includes a plurality of conductive holes extending along the thickness direction of the mating circuit board. Some of the plurality of conductive holes connect the plurality of first ground pads 304a and the plurality of second ground pads 304b with the first metal grounding plate 305a and the third metal grounding plate 305c in series. Another some of the plurality of conductive holes connect the plurality of third ground pads 304c and the plurality of fourth ground pads 304d with the second metal grounding plate 305b and the third metal grounding plate 305c in series. As a result, the plurality of first ground pads 304a, the plurality of second ground pads 304b, the plurality of third ground pads 304c, the plurality of fourth ground pads 304d, the first metal grounding plate 305a, the second metal grounding plate 305b and the third metal grounding plate 305c are all connected in series to form a whole, so as to increase the shared grounding area and improve the quality of signal transmission.

In the illustrated embodiment of the present disclosure, the mating circuit board includes an end surface 307 at a front end thereof. The first metal grounding plate 305a, the second metal grounding plate 305b and the third metal grounding plate 305c all extend forwardly at least adjacent to the end surface 307. In the second embodiment shown in the present disclosure, the mating circuit board includes a connecting plate 308 disposed on a mating edge of the mating circuit board. The connecting plate 308 is perpendicular to the plurality of layers of metal grounding plates 305. The connecting plate 308 is in contact with the plurality of layers of the metal grounding plates 305 so as to increase the shared grounding area.

In the present disclosure, by providing the plurality of layers of metal grounding plates 305, the signal pads 303 on two sides of the plurality of layers of metal grounding plates 305 can be internally isolated, thereby reducing crosstalk. In addition, the first metal grounding plate 305a, the second metal grounding plate 305b and the third metal grounding plate 305c are electrically connected to the shielding assembly of the electrical connector 100 through the connecting plate 308, thereby improving the shielding effect. Compared with the first metal grounding plate 305a, the second metal grounding plate 305b and the third metal grounding plate 305c directly contacting the shielding assembly of the electrical connector 100, in the second embodiment of the present disclosure, the contact area is increased and the contact reliability is improved by providing the connecting plate 308.

The first shielding assembly 3a includes a first metal shielding sheet 31, a second metal shielding sheet 32, a plurality of third metal shielding sheets 33 and a plurality of fourth metal shielding sheets 34. In the illustrated embodiment of the present disclosure, the first metal shielding sheet 31, the second metal shielding sheet 32, the third metal shielding sheets 33 and the fourth metal shielding sheets 34 are separated components, but assembled together. It is understandable to those skilled in the art that the first metal shielding sheet 31, the second metal shielding sheet 32, the third metal shielding sheets 33 and the fourth metal shielding sheets 34 may also be in one-piece structure, or at least two metal shielding sheets in one-piece structure.

In the illustrated embodiment of the present disclosure, the second metal shielding sheet 32 further includes a plurality of first abutting elastic arms 324 protruding into the mating slot 110. The plurality of first abutting elastic arms 324 are disposed at intervals along the first direction A1-A1. In the illustrated embodiment of the present disclosure, the first abutting elastic arms 324 are integrally formed with the second metal shielding sheet 32. Each first abutting elastic arm 324 is in a cantilever shape. The first abutting elastic arm 324 has a first abutting portion 3241 protruding into the mating slot 110. The first abutting portion 3241 is configured to be in contact with the connecting plate 308. As a result, on the one hand, the first abutting elastic arm 324 can provide a certain elastic force to the mating module 300; on the other hand, the first shielding assembly 3a can be in series connected with a whole formed by the plurality of first ground pads 304a, the plurality of second ground pads 304b, the plurality of third ground pads 304c, the plurality of fourth ground pads 304d, the first metal grounding plate 305a, the second metal grounding plate 305b, the third metal grounding plate 305c and the connecting plate 308. Of course, it is understandable to those skilled in the art that the first abutting elastic arm 324 can also be replaced by a structure such as a simply supported beam.

The second shielding assembly 3b includes a fifth metal shielding sheet 35, a sixth metal shielding sheet 36, a plurality of seventh metal shielding sheets 37 and a plurality of eighth metal shielding sheets 38. In the embodiment shown in the present disclosure, the fifth metal shielding sheet 35, the sixth metal shielding sheet 36, the seventh metal shielding sheets 37 and the eighth metal shielding sheets 38 are separated components, but assembled together. It is understandable to those skilled in the art that the fifth metal shielding sheet 35, the sixth metal shielding sheet 36, the seventh metal shielding sheets 37 and the eighth metal shielding sheets 38 may also be in one-piece structure, or at least two metal shielding sheets in one-piece structure.

In the illustrated embodiment of the present disclosure, the sixth metal shielding sheet 36 further includes a plurality of second abutting elastic arms 364 protruding into the mating slot 110. The plurality of second abutting elastic arms 364 are disposed at intervals along the first direction A1-A1. In the illustrated embodiment of the present disclosure, the second abutting elastic arms 364 are integrally formed with the sixth metal shielding sheet 36. Each second abutting elastic arm 364 is in a cantilever shape. The second abutting elastic arm 364 has a second abutting portion 3641 protruding into the mating slot 110. The second abutting portion 3641 is configured to be in contact with the connecting plate 308. Of course, it is understandable to those skilled in the art that the second abutting elastic arm 364 can also be replaced by a less elastic structure such as simply supported beam, or even replaced by a non-elastic structure.

As shown in FIG. 35 and FIG. 36, in a third embodiment of the present disclosure, the mating module 300 is a plug connector, such as an SFP (Small Form-Factor Pluggable) plug cable connector. The plug connector includes a tongue plate. In the third embodiment, the tongue plate is a mating circuit board formed by a built-in circuit board. The mating circuit board includes a first surface 301, a second surface 302 opposite to the first surface 301, a plurality of signal pads 303 exposed to the first surface 301 and/or the second surface 302, a plurality of ground pads 304 exposed to the first surface 301 and/or the second surface 302, and a plurality of layers of metal grounding plates 305 located between the first surface 301 and the second surface 302. The plurality of layers of metal grounding plates 305 include a first metal grounding plate 305a and a second metal grounding plate 305b which are arranged at intervals along a thickness direction of the mating circuit board.

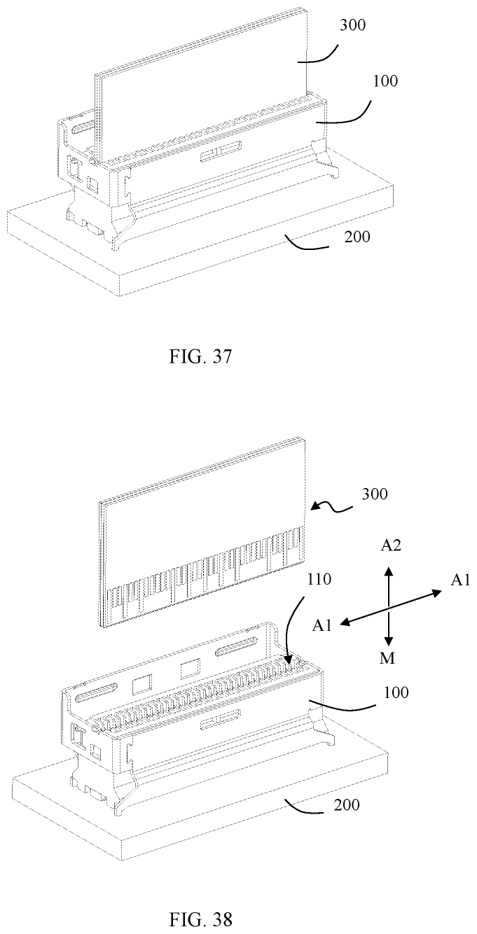

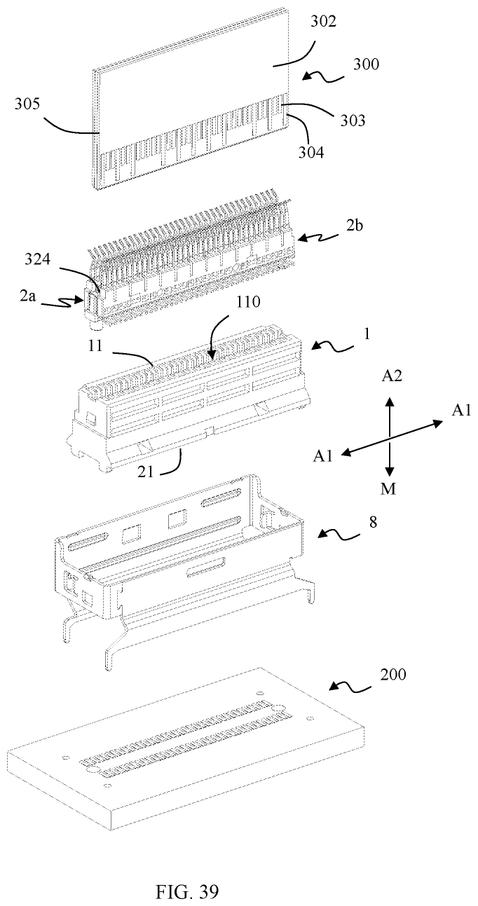

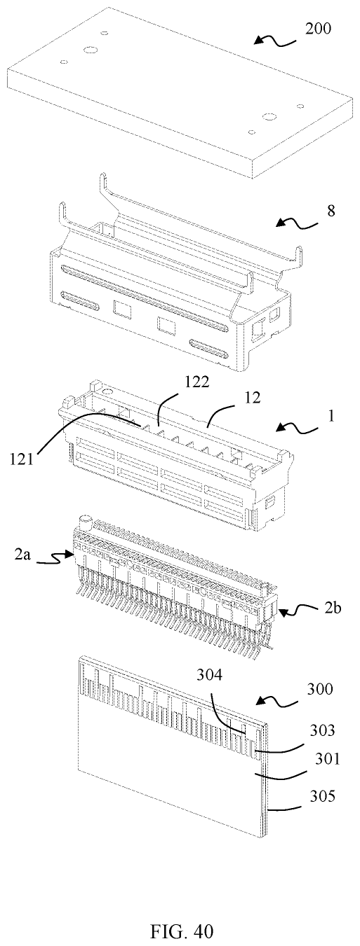

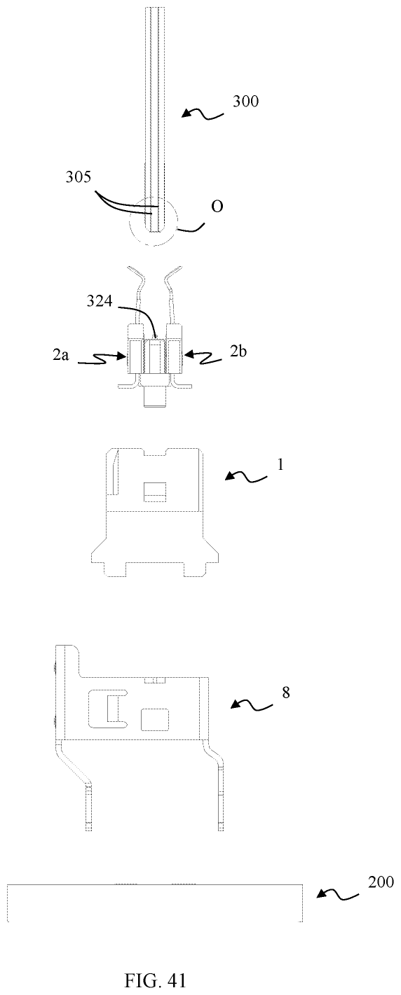

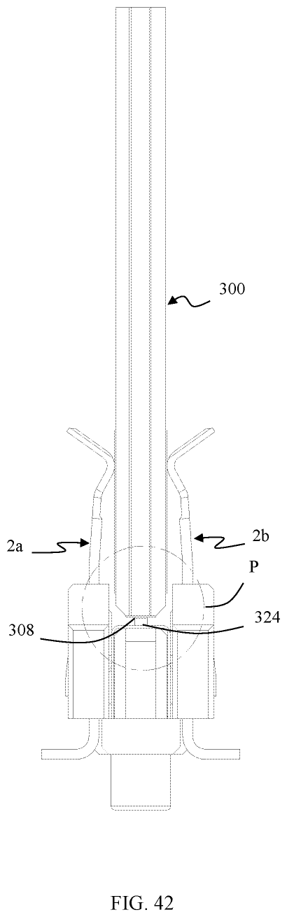

Referring to FIG. 37 to FIG. 44, in a fourth embodiment of the connector assembly of the present disclosure, the connector assembly includes an electrical connector 100 and a mating module 300 mated with the electrical connector 100. The electrical connector 100 is configured to be installed on a circuit board 200 and configured to be at least partially inserted into the mating module 300. In the fourth embodiment, the mating module 300 is an electronic card, and the electrical connector 100 is a card edge connector accordingly. The electronic card includes a tongue plate. In this embodiment, the tongue plate is a mating circuit board which is configured for being at least partially inserted into the electrical connector 100.

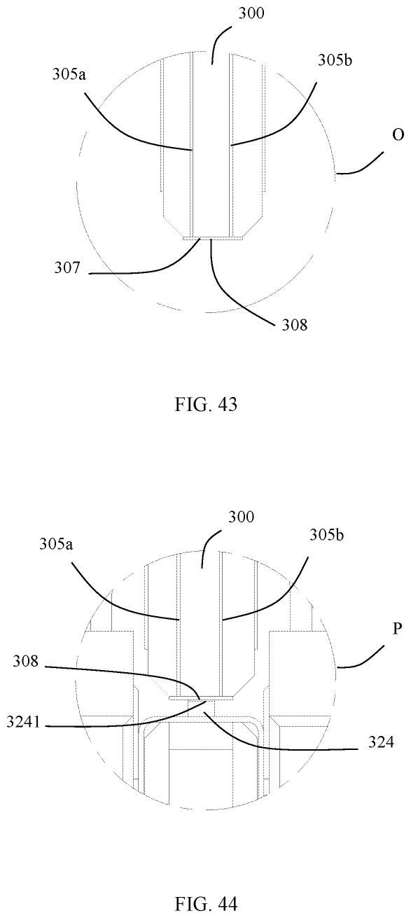

Referring to FIG. 43 and FIG. 44, the mating circuit board of the mating module 300 includes a first surface 301, a second surface 302 opposite to the first surface 301, a plurality of signal pads 303 exposed to the first surface 301 and the second surface 302, a plurality of ground pads 304 exposed to the first surface 301 and the second surface 302, and a plurality of layers of metal grounding plates 305 located between the first surface 301 and the second surface 302.

In the fourth embodiment, the plurality of layers of metal grounding plates 305 include a first metal grounding plate 305a and a second metal grounding plate 305b which are arranged at intervals along a thickness direction of the mating circuit board. The mating circuit board further includes a plurality of conductive holes (not shown) extending along the thickness direction of the mating circuit board. The plurality of conductive holes connect the first metal grounding plate 305a and the second metal grounding plate 305b in series, so as to increase the shared ground area, thereby improving the quality of signal transmission.

Referring to FIG. 43 and FIG. 44, in the illustrated embodiment of the present disclosure, the mating circuit board includes an end surface 307 at a lower end thereof. The first metal grounding plate 305a and the second metal grounding plate 305b at least extend adjacent to the end surface 307. The mating circuit board further includes a connecting plate 308 disposed on a mating edge of the mating circuit board. The connecting plate 308 is perpendicular to the plurality of layers of metal grounding plates 305. The connecting plate 308 is configured to be in contact with the plurality of layers of the metal grounding plates 305 so as to increase the shared grounding area.

In the present disclosure, by providing the plurality of layers of metal grounding plates 305, the signal pads 303 on two sides of the plurality of layers of metal grounding plates 305 can be internally isolated, thereby reducing crosstalk. In addition, the first metal grounding plate 305a and the second metal grounding plate 305b are electrically connected to the shielding assembly of the electrical connector 100 through the connecting plate 308 so as to improve the shielding effect. Compared with the first metal grounding plate 305a and the second metal grounding plate 305b directly in contact with the shielding assembly of the electrical connector 100, in the present disclosure, the contact area is increased and the contact reliability is improved by providing the connecting plate 308.

Referring to FIG. 38 to FIG. 42, the electrical connector 100 includes an insulating body 1, a first terminal module 2a assembled to the insulating body 1, a second terminal module 2b assembled to the insulating body 1, a metal shielding sheet mounted to the insulating body 1, and a metal shell 8 sleeved on the insulating body 1.

The insulating body 1 includes a mating surface 11, a mating slot 110 extending through the mating surface 11, a mounting surface 12 opposite to the mating surface 11, a first installation slot 121 extending through the mounting surface 12, and a second installation slot 122 extending through the mounting surface 12. Both the first installation slot 121 and the second installation slot 122 communicate with the mating slot 110. The mating slot 110 is configured to receive at least part of the mating circuit board along an insertion direction M (for example, a top-to-bottom direction). The first installation slot 121 and the second installation slot 122 are used for accommodating the first terminal module 2a and the second terminal module 2b, respectively.

The metal shielding sheet includes a plurality of first abutting elastic arms 324 protruding into the mating slot 110 along the second direction A2. The plurality of first abutting elastic arms 324 are disposed at intervals along the first direction A1-A1. In the illustrated embodiment of the present disclosure, the first abutting elastic arms 324 and the metal shielding sheet are integrally formed (for example, formed by integral stamping). Each first abutting elastic arm 324 is in an inclined cantilever shape. The first abutting elastic arm 324 includes a first abutting portion 3241 protruding into the mating slot 110 along the second direction A2. The first abutting portion 3241 is configured to abut against the connecting plate 308. With such arrangement, on the one hand, the first abutting elastic arm 324 can provide a certain elastic support to the mating module 300; on the other hand, it is beneficial to improve the grounding shielding effect. Of course, it is understandable to those skilled in the art that the first abutting elastic arm 324 can also be replaced by a structure such as a simply supported beam.

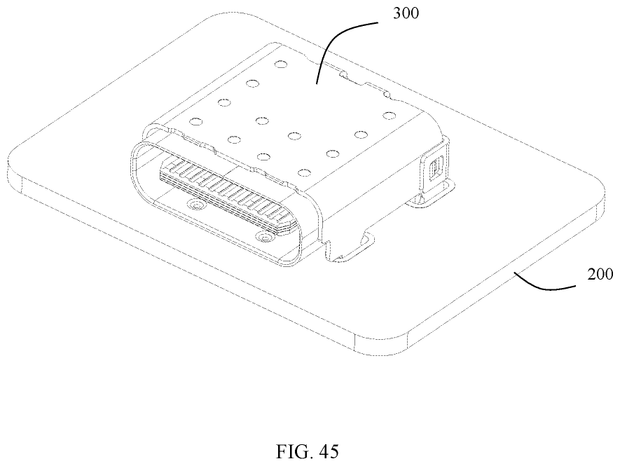

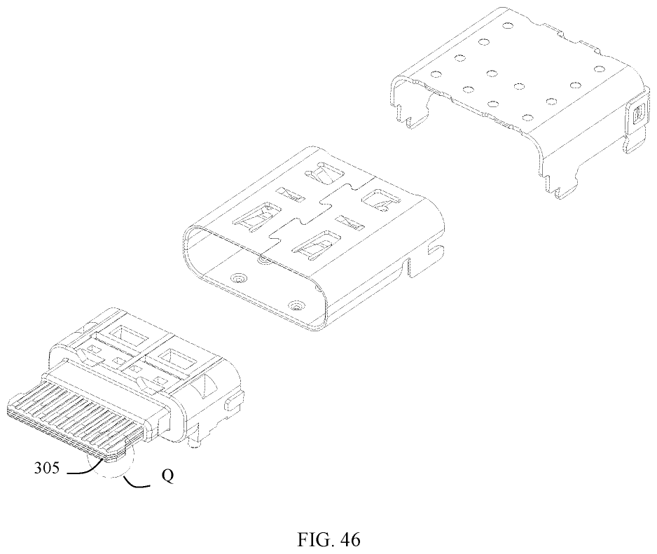

Referring to FIG. 45 to FIG. 47, in a fifth embodiment of the mating module 300 of the present disclosure, the mating module 300 is configured to be installed on a circuit board 200. In the fifth embodiment, the mating module 300 is a USB Type-C receptacle connector. The mating module 300 includes a tongue plate. The tongue plate is at least partially inserted into a mating slot of a mating connector. In one embodiment of the present disclosure, most of the tongue plate is made of insulating material. At least one layer of metal grounding plate 305 is embedded in the tongue plate. In another embodiment of the present disclosure, the tongue plate is a mating circuit board.

The tongue plate includes a first surface 301 (for example, an upper surface), a second surface 302 (for example, a lower surface) opposite to the first surface 301, a plurality of signal pads 303 exposed to the first surface 301 and the second surface 302, a plurality of ground pads 304 exposed to the first surface 301 and the second surface 302, and a plurality of layers of metal grounding plates 305 located between the first surface 301 and the second surface 302.

In this embodiment, the plurality of layers of metal grounding plates 305 include a first metal grounding plate 305a, a second metal grounding plate 305b and a third metal grounding plate 305c which are arranged at intervals along a thickness direction of the tongue plate. The third metal grounding plate 305c is located between the first metal grounding plate 305a and the second metal grounding plate 305b. The tongue plate further includes a conductive portion (not shown) extending along the thickness direction of the tongue plate. The conductive portion connects the first metal grounding plate 305a, the second metal grounding plate 305b and the third metal grounding plate 305c in series so as to increase the shared ground area and improve the quality of signal transmission.

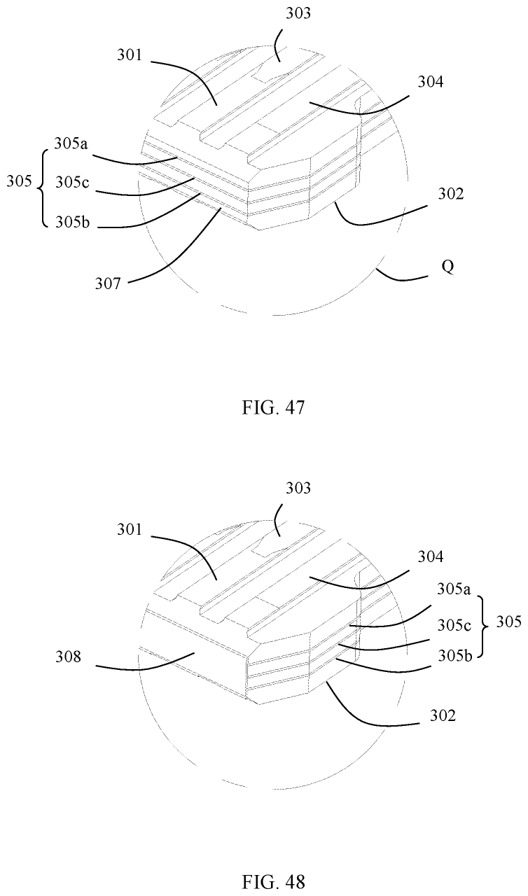

Referring to FIG. 47, in the illustrated embodiment of the present disclosure, the tongue plate includes an end surface 307 at a front end thereof. The first metal grounding plate 305a, the second metal grounding plate 305b and the third metal grounding plate 305c at least extend adjacent to the end surface 307. In the embodiment shown in FIG. 47, the first metal grounding plate 305a, the second metal grounding plate 305b and the third metal grounding plate 305c are all exposed to the end surface 307, so as to facilitate electrical connection with a metal shielding sheet (not shown). Of course, it is understandable to those skilled in the art that, in some embodiments, the first metal grounding plate 305a, the second metal grounding plate 305b and the third metal grounding plate 305c may also protrude forwardly beyond the end surface 307 so as to improve the reliability when contacting the metal shielding sheet of the electrical connector 100.

Referring to FIG. 48, in another illustrated embodiment of the present disclosure, the tongue plate further includes a connecting plate 308 provided on a mating edge of the tongue plate. The connecting plate 308 is perpendicular to the plurality of layers of metal grounding plates 305. The connecting plate 308 is in contact with the plurality of layers of the metal grounding plates 305 to increase the shared grounding area.

In the present disclosure, by providing the plurality of layers of metal grounding plates 305, the signal pads 303 on two sides of the plurality of layers of metal grounding plates 305 can be internally isolated, thereby reducing crosstalk. In addition, the first metal grounding plate 305a and the second metal grounding plate 305b are electrically connected to the metal shielding sheet of the electrical connector 100 through the connecting plate 308 so as to improve the shielding effect. Compared with the first metal grounding plate 305a, the second metal grounding plate 305b and the third metal grounding plate 305c in direct contact with the metal shielding sheet of the electrical connector 100, in the present disclosure, the contact area is increased and the contact reliability is improved by providing the connecting plate 308.

It is understandable to those skilled in the art that the mating module 300 shown in the illustrated embodiments of the present disclosure can be transferred to any mating connector with a tongue plate, such as USB 3.0 plug connector, a DMHI receptacle connector and a DisplayPort receptacle connector, etc., to achieve the purpose of the present disclosure, which will not be repeated herein.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A mating module, comprising: a tongue plate configured to be inserted into a mating slot of an electrical connector; the tongue plate comprising a first surface, a second surface opposite to the first surface, a conductive pad exposed to the first surface and/or the second surface, and at least one layer of metal grounding plate located between the first surface and the second surface; an end surface of the metal grounding plate extending at least adjacent to an edge of the tongue plate; the end surface of the metal grounding plate being configured to be electrically connected to a metal shielding sheet of the electrical connector.

2. The mating module according to claim 1, wherein the metal grounding plate comprises a first metal grounding plate and a second metal grounding plate which are disposed at intervals along a thickness direction of the tongue plate; the first metal grounding plate and the second metal grounding plate are parallel to each other; both an end surface of the first metal grounding plate and an end surface of the second metal grounding plate are exposed to the edge of the tongue plate.

3. The mating module according to claim 2, wherein the tongue plate is a mating circuit board; the mating circuit board comprises conductive holes; and the first metal grounding plate and the second metal grounding plate are connected through the conductive holes.

4. The mating module according to claim 1, wherein the metal grounding plate comprises a first metal grounding plate and a second metal grounding plate; the first metal grounding plate and the second metal grounding plate are parallel to each other;
the tongue plate comprises a connecting pad provided on a mating edge of the tongue plate; the connecting pad is perpendicular to the first metal grounding plate and the second metal grounding plate; the connecting pad is in contact with the first metal grounding plate and the second metal grounding plate; the connecting pad is configured to be in contact with the metal shielding sheet of the electrical connector.

5. An electrical connector, comprising:
an insulating body comprising a mating surface and a mating slot extending through the mating surface; the mating slot being configured to receive at least part of a mating module along an insertion direction; the mating module being configured to comprise a first surface, a second surface opposite to the first surface, a conductive pad exposed to the first surface and/or the second surface, and at least one layer of metal grounding plate located between the first surface and the second surface; an end surface of the metal grounding plate extending at least adjacent to an edge of the mating module;
a plurality of first conductive terminals, each first conductive terminal comprising a first contact portion protruding into the mating slot; the first contact portion being configured to be in contact with the conductive pad of the mating module; and
a metal shielding sheet comprising a first abutting portion protruding into the mating slot along a second direction opposite to the insertion direction; the first abutting portion being configured to be electrically connected to the end surface of the metal grounding plate.

6. The electrical connector according to claim 5, wherein the metal shielding sheet comprises a first abutting elastic arm; the first abutting portion is provided on the first abutting elastic arm;
the first abutting elastic arm is integrally formed with the metal shielding sheet.

7. The electrical connector according to claim 6, wherein the first abutting elastic arm is in a cantilever shape.

8. The electrical connector according to claim 6, wherein a plurality of first abutting elastic arms are provided and disposed at intervals along a first direction; the first direction is perpendicular to the second direction.

9. The electrical connector according to claim 5, further comprising a plurality of first terminal modules; each first terminal module comprising a first insulating block and the plurality of first conductive terminals fixed to the first insulating block; each first conductive terminal comprising a first fixing portion fixed to the first insulating block and a first elastic arm extending from the first fixing portion; the first elastic arm comprising the first contact portion; the plurality of first conductive terminals comprising a first signal terminal and a second signal terminal which is located adjacent to the first signal terminal along a first direction; the first direction being perpendicular to the second direction; the first signal terminal and the second signal terminal which is located adjacent to the first signal terminal together form a terminal group;
the metal shielding sheet comprising a first metal shielding sheet, a second metal shielding sheet, a third metal shielding sheet and a fourth metal shielding sheet; the first metal shielding sheet being located on a first side of the terminal group; the second metal shielding sheet being disposed opposite to the first metal shielding sheet; the second metal shielding sheet being located on a second side of the terminal group; the third metal shielding sheet being located between the first metal shielding sheet and the second metal shielding sheet; the third metal shielding sheet being disposed on a third side of the terminal group; the fourth metal shielding sheet being disposed between the first metal shielding sheet and the second metal shielding sheet; the fourth metal shielding sheet being disposed opposite to the third metal shielding sheet; the fourth metal shielding sheet being located on a fourth side of the terminal group;
wherein the first metal shielding sheet, the second metal shielding sheet, the third metal shielding sheet and the fourth metal shielding sheet are disposed around a periphery of the terminal group;
the first abutting portion is provided on the second metal shielding sheet.

10. The electrical connector according to claim 9, wherein the third metal shielding sheet comprises a first elastic engaging portion protruding into the mating slot; the first direction is perpendicular to the insertion direction;
the fourth metal shielding sheet comprises a second elastic engaging portion protruding into the mating slot;
the first elastic engaging portion and the second elastic engaging portion are configured to be in contact with a first ground pad and a second ground pad of the mating module, respectively.

11. The electrical connector according to claim 10, wherein the third metal shielding sheet comprises a first elastic simply supported beam and a first slot which provides a space for deformation of the first elastic simply supported beam; two ends of the first elastic simply supported beam are fixed to the third metal shielding sheet, respectively; the first elastic engaging portion is provided on the first elastic simply supported beam; and
wherein the fourth metal shielding sheet comprises a second elastic simply supported beam and a second slot which provides a space for deformation of the second elastic simply supported beam; two ends of the second elastic simply supported beam are fixed to the fourth metal shielding sheet, respectively; the second elastic engaging portion is provided on the second elastic simply supported beam.

12. The electrical connector according to claim 11, wherein the first elastic simply supported beam is wavy or arc-shaped; at least two first elastic engaging portions are provided and arranged at intervals along the second direction; and
wherein the second elastic simply supported beam is wavy or arc-shaped; at least two second elastic engaging portions are provided and arranged at intervals along the second direction.

13. The electrical connector according to claim 9, wherein the terminal group is a first differential signal terminal pair; the first metal shielding sheet, the second metal shielding sheet, the third metal shielding sheet and the fourth metal shielding sheet surround a periphery of the first fixing portions of the first differential signal terminal pair.

14. The electrical connector according to claim 13, wherein the first metal shielding sheet, the third metal shielding sheet and the fourth metal shielding sheet extend along the second direction to be flush with a top surface of the first conductive terminal or protrude beyond the top surface;
the second metal shielding sheet is lower than the top surface along the second direction.

15. The electrical connector according to claim 14, wherein the first metal shielding sheet, the third metal shielding sheet and the fourth metal shielding sheet form a first U-shaped cavity corresponding to the first elastic arms of the terminal group; the first U-shaped cavity comprises a first opening through which the first contact portions of the terminal group protrude into the mating slot.

16. The electrical connector according to claim 15, wherein when the mating module is inserted into the mating slot, the first opening is shielded by the metal grounding plate so as to surround the first elastic arms of the first differential signal terminal pair.

17. The electrical connector according to claim 13, wherein the metal grounding plate comprises a first metal grounding plate and a second metal grounding plate; the first metal grounding plate and the second metal grounding plate are parallel to each other and connected together; an end surface of the first metal grounding plate and an end surface of the second metal grounding plate are exposed to an edge of the mating module;
wherein the electrical connector further comprises:
a plurality of second terminal modules, each second terminal module comprising a second insulating block and a plurality of second conductive terminals fixed to the second insulating block; each second conductive terminal comprising a second fixing portion fixed to the second insulating block and a second elastic arm extending from the second fixing portion; the second elastic arm comprising a second contact portion protruding into the mating slot; the plurality of second conductive terminals comprising a third signal terminal and a fourth signal terminal which is located adjacent to the third signal terminal; the third signal terminal and the fourth signal terminal are disposed side by side along the first direction to form a second differential signal terminal pair;
a fifth metal shielding sheet located on a first side of the second differential signal terminal pair;
a sixth metal shielding sheet disposed opposite to the fifth metal shielding sheet; the sixth metal shielding sheet being located on a second side of the second differential signal terminal pair;
a seventh metal shielding sheet disposed between the fifth metal shielding sheet and the sixth metal shielding sheet; the seventh metal shielding sheet being located on a third side of the second differential signal terminal pair; and
an eighth metal shielding sheet disposed between the fifth metal shielding sheet and the sixth metal shielding sheet; the eighth metal shielding sheet being disposed opposite to the seventh metal shielding sheet; the eighth metal shielding sheet being located on a fourth side of the second differential signal terminal pair;
wherein the fifth metal shielding sheet, the sixth metal shielding sheet, the seventh metal shielding sheet and the eighth metal shielding sheet are disposed around a periphery of the second differential signal terminal pair;
the sixth metal shielding sheet comprises a second abutting portion protruding into the mating slot along the second direction; the first abutting portion is configured to be electrically connected to the end surface of the first metal grounding plate; the second abutting portion is configured to be electrically connected to the end surface of the second metal grounding plate.

18. A connector assembly, comprising:
a mating module, the mating module comprising a tongue plate; the tongue plate comprising a first surface, a second surface opposite to the first surface, a conductive pad exposed to the first surface and/or the second surface, and at least one layer of metal grounding plate located between the first surface and the second surface; an end surface of the metal grounding plate extending at least adjacent to an edge of the tongue plate; and
an electrical connector comprising an insulating body, a plurality of first conductive terminals and a metal shielding sheet;
the insulating body comprising a mating surface and a mating slot extending through the mating surface; the mating slot being configured to receive at least part of the mating module along an insertion direction;
each first conductive terminal comprising a first contact portion protruding into the mating slot; the first contact portion being configured to be in contact with the conductive pad of the mating module;
the metal shielding sheet comprising a first abutting portion protruding into the mating slot along a second direction opposite to the insertion direction; the first abutting portion being configured to be electrically connected to the end surface of the metal grounding plate.

19. The connector assembly according to claim 18, wherein the metal grounding plate comprises a first metal grounding plate and a second metal grounding plate which are disposed at intervals along a thickness direction of the tongue plate; the first metal grounding plate and the second metal grounding plate are parallel to each other; both an end surface of the first metal grounding plate and an end surface of the second metal grounding plate are exposed to the edge of the tongue plate.

20. The connector assembly according to claim 18, wherein the metal grounding plate comprises a first metal grounding plate and a second metal grounding plate; the first metal grounding plate and the second metal grounding plate are parallel to each other;
the tongue plate comprises a connecting pad provided on a mating edge of the tongue plate; the connecting pad is perpendicular to the first metal grounding plate and the second metal grounding plate; the connecting pad is in contact with the first metal grounding plate and the second metal grounding plate; the connecting pad is configured to be in contact with the metal shielding sheet of the electrical connector.
